(19) United States
(12) Patent Application Publication
(10) Pub. No.: US 2012/0085992 A1
(43) Pub. Date: Apr. 12, 2012

(54) Furan Conjugated Polymers Useful for Photovoltaic Applications

(75) Inventors: Pierre M. Beaujuge, Berkeley, CA (US); Claire H. Woo, Berkeley, CA (US); Jean M.J. Frechet, Oakland, CA (US)

(73) Assignee: The Regents of the University of California, Oakland, CA (US)

(21) Appl. No.: 13/251,044

(22) Filed: Sep. 30, 2011

Related U.S. Application Data
(60) Provisional application No. 61/388,479, filed on Sep. 30, 2010.

(51) Int. Cl. H01L 51/50; H01B 1/12; C08G 75/06; C08G 73/06

(52) U.S. Cl. 257/40; 528/9; 252/501.1; 257/E51.024

(57) ABSTRACT

The present invention provides for a polymer comprising a π-conjugated backbone comprising a furan. The polymer has a narrow or low band gap and/or is solution processable. In some embodiments, the polymer is PDPP2FT or PDPP3F. The present invention also provides for a device comprising the polymer, such as a light-emitting diode, thin-film transistor, chemical biosensor, non-emissive electrochromic, memory device, photovoltaic cells, or the like.

### CROSS-REFERENCE TO RELATED APPLICATIONS

This application claims priority to U.S. Provisional Patent Application Ser. No. 61/388,479, filed Sep. 30, 2010, which is hereby incorporated by reference in its entirety.

### STATEMENT OF GOVERNMENTAL SUPPORT

The invention was made with government support under Contract Nos. DE-AC02-05CH11231 awarded by the U.S. Department of Energy. The government has certain rights in the invention.

### FIELD OF THE INVENTION

The present invention is in the field of photovoltaics.

### BACKGROUND OF THE INVENTION

The semiconducting properties of π-conjugated polymers, whereby a multiplicity of π-aromatic units are covalently appended to yield a conjugated backbone capable to harvest light and transport charges, are presently being exploited in a number of device applications spanning light-emitting diodes, thin-film transistors, chemical biosensors, non-emissive electrochromics, memory devices, and photovoltaic cells. In a context of fast-growing demand for innovative, high-performance, and mechanically flexible light-harvesting technologies, π-conjugated polymers represent a cost-effective alternative to conventional silicon-based technologies that frequently involve high-manufacturing costs and throughput limitations inherent to the high-temperature/high-vacuum processing techniques employed. In contrast, π-conjugated polymers combine synthetic accessibility and versatility, ease in bandgap engineering, mechanical conformability, potential for low-cost scalability and high-throughput solution processing. These are properties especially appealing on the emerging market of large-area solar cells for car and housing roof tops, or for portable devices made of printed photoactive arrays.

Introduced in macromolecular systems by Havinga et al. in the early 1990's, the ‘donor-acceptor’(DA) approach alternates electron-rich (donor) and electron-deficient (acceptor) π-aromatic units along a polymer backbone to produce semiconducting organics with narrow energy gaps. A direct consequence of the narrow band gap produced following this approach is an optical spectrum shifted towards the long wavelengths (i.e. in the 500-1000 nm region), where the solar photon flux is the most intense. While the top of the valence band (i.e. its energy level) is typically governed by the most electron-rich units in the backbone, the bottom of the conduction band is dominated by the most electron-deficient substituents, and a relatively independent control of these band edges can in turn be obtained by carefully choosing the nature of the building blocks incorporated along the conjugated backbones. In addition, the donor-acceptor interaction is expected to yield particularly tight intermolecular spacings (i.e. close stacking between π-aromatic segments) facilitating the transport of charges from backbone to backbone. This method has been used to produce the highest-performing π-conjugated polymers to date (used as the p-type component) for organic bulk p-n junction solar cells with fullerenes (used as the n-type component); see Chart 1 (donor units in red, acceptor units in blue).

As illustrated in Chart 1, high-performing semiconducting polymers for photovoltaic applications have systematically incorporated thiophene and/or thiophene-based π-aromatic units as the electron-rich component, which has significantly restricted the range of donor-acceptor combinations used in producing high-performance photovoltaic materials. The best performing of these polymers (PBDTTT, see Chart 1) exhibits up to 7.8% of power conversion efficiency (PCE) in solar cells with fullerenes, and further involves an all-thiophene based electron-deficient core. The well-established synthetic versatility and ambient stability of thiophene and thiophene-based precursors have most likely represented the primary reason for their near-exclusive integration in photovoltaic polymers. Selenophenes have recently emerged as an alternative to thiophene, yet without clear promises over the thiophene counterparts in terms of photovoltaic performance. While the manufacturing of thiophene precursors involves the use of relatively toxic and environmentally harmful sulfur sources (e.g. carbon disulfide CS₂, phosphorus decasulfide P₄S₁₀, phosphorus heptasulfide P₄S₇, Lawesson's reagent, S₈), the particularly high level of toxicity of selenium sources and the resulting selenophene precursors have clearly hindered the research and development of selenophene-based semiconducting organics so far. Based on these considerations, near-future large-scale industrial manufacturing of selenophene precursors is unlikely.

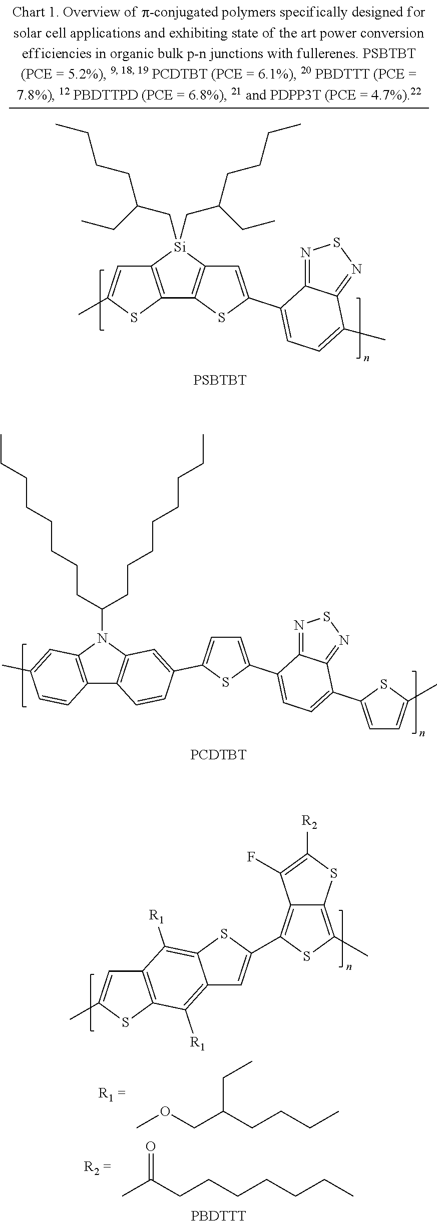

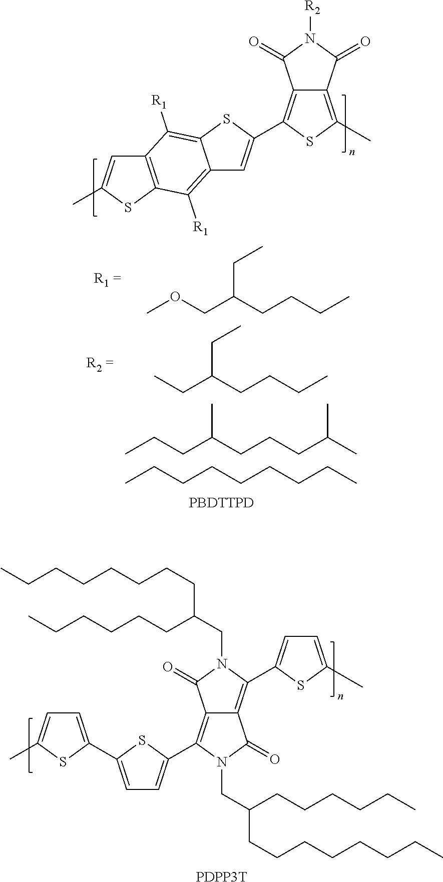

In contrast, furan and furan-based π-aromatic units have been largely neglected as building blocks for the design and synthesis of π-conjugated polymers potentially useful for organic electronic applications. In particular, the potential of furan-based π-conjugated polymers for photovoltaic applications has not been identified so far, and the perspectives of furan-containing π-aromatic units as thiophene alternatives remain unknown to date. A few relatively common assumptions including: 1) expected lack of ambient stability of both small molecule precursors and polymers, and 2) common assumption that thiophene is the best possible aromatic unit for organic electronic applications, can possibly explain the lack of research effort directed to elucidating the potential of furan in organic photovoltaics. It is important to note that furan and furan-based precursors can be made from a variety of natural products (e.g. corncobs, oat, wheat bran, sawdust, and more broadly by hydrolysis of polymers of sugar), and they can in turn be considered renewable and sustainable synthetic resources. The ability to mass-produce organic photovoltaics directly from non-toxic and environmentally harmless precursors could have a tremendous impact on the industrial development of this technology, and on its long-term viability in the context of an economy/market typically hindered by material resources (e.g. indium and gallium in the case of silicon-based semiconducting technologies). Based on these considerations, furan-based photovoltaics could be anticipated to rapidly replace thiophene-based systems in mass-produced devices. It is also worth noting that in the case where the performance of furan-based photovoltaic polymers remains inferior to that of their all-thiophene analogs, the scalability and environmental sustainability of the furan-alternatives may ultimately prevail with respect to large-scale industrial manufacturing processes.

### SUMMARY OF THE INVENTION

The present invention provides for a polymer comprising a π-conjugated backbone wherein the π-conjugated backbone comprising a furan. The polymer has a narrow or low band gap and/or is solution processable. In some embodiments, the π-conjugated backbone comprises of a covalently bonded series of repeating monomers. In some embodiments, the repeating monomer comprises one or more furans. In some embodiments, the repeating monomer comprises two or more, or three or more, furans.

The invention also provides for a method of making the polymer of the present invention comprising a method described herein.

The invention also provides for a composition or a device comprising the polymer of the present invention. In some embodiments, the device is a light-emitting diode, thin-film transistor, chemical biosensor, non-emissive electrochromic, memory device, photovoltaic cells, or the like. In some embodiments, the device comprises (a) the polymer of the present invention which is a p-type component (i.e. electron-donor) and (b) a suitable n-type component (i.e. electron-acceptor).

The invention also provides for a photovoltaic device comprising a photoactive layer comprising the polymer of the present invention disposed between a first electrode and a second electrode. In some embodiments, the first electrode is ITO. In some embodiments, the second electrode is LiF/Al. In some embodiments, the photoactive layer, the first electrode, and the second electrode are thin films. In some embodiments, the thin films are disposed on a suitable substrate. In some embodiments, the substrate comprises glass. A photovoltaic solar cell of the present invention has an efficiency equal to at least about 5%, 6%, or 10%.

In some embodiments, the polymers of the present invention are capable of absorbing light. In some embodiments, the polymers of the present invention, when in a photovoltaic device, such as a solar cell, are capable of conducting charges perpendicular to the film.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 shows: a) Synthetic scheme and polymeric structures used in this study (polymerization protocol: Pd₂dba₃, P(o-tol)₃, chlorobenzene, 110° C., 24 h). b) Thin film absorption spectra and c) cyclic voltammograms of PDPP2FT and PDPP3F.

FIG. 2 shows: a) J-V curves of optimized PDPP2FT:PC₇₁BM devices spin-coated out of chlorobenzene (with no additive and with 9 vol % CN). b) External quantum efficiency spectra of optimized devices.

FIG. 3 shows AFM phase images of 1:3 PDPP2FT:PC₇₁BM blend films spin-coated (a) from chlorobenzene only and (b) from chlorobenzene+9 vol % CN. (Inset: height images of the same films. The data scale is 0-60 nm.)

FIG. 4 shows: a) SEC trace of PDPP2FT. Mₙ=66 kDa, PDI=2.05. b) SEC trace of PDPP3F. Mₙ=29 kDa, PDI=2.02. c) SEC trace of the soluble fraction of PDPP3T. Mₙ=2 kDa, PDI=2.71.

FIG. 5 shows the absorption spectra of PDPP2FT thin films as spun from pure chlorobenzene and from chlorobenzene with 5 vol % CN added.

FIG. 6 shows J-V curves and EQE spectra of optimized 1:3 PDPP2FT:PC₆₁BM BHJ devices fabricated without additive and with 1 vol % CN.

FIG. 7 shows J-V curves of optimized 1:3 PDPP3F:PC₆₁BM (left) and 1:3 PDPP3F:PC₇₁BM (right) fabricated without additive and with 5 vol % CN.

FIG. 8 shows AFM height (left) and phase images (right) of PDPP2FT:PC₆₁BM blends at 1:3 ratio by weight. a) spun from chlorobenzene only. b) spun from chlorobenzene+1 vol % CN.

FIG. 9 shows: a) J-V curves of optimized PDPP2FT:PC₇₁BM devices spin-coated out of chlorobenzene (with no additive and with 9 vol % CN). b) External quantum efficiency spectra of the same devices.

FIG. 10 shows the absorption spectra of PDPP2FT thin films as spun from pure chlorobenzene and from chlorobenzene with 5 vol % CN added.

FIG. 11 shows the synthesis of PDPP2FT derivatives with alkyl side-chains of varying size and bulk.

FIG. 12 shows the average J-V curves (A) and characteristic external quantum efficiency (EQE) spectra (B) of solar cells fabricated from PDPP2FT-C₁₂, -C₁₄, and -C₁₆.

FIG. 13 shows the AFM height (left) and phase (right) images of the n-alkyl-substituted polymers a) PDPP2FT-C₁₂, b) PDPP2FT-C₁₄, and c) PDPP2FT-C₁₆.

FIG. 14 shows the 2-D grazing incidence x-ray scattering (GIXS) patterns of thin films of a) PDPP2FT-C₁₂, b) PDPP2FT-C₁₄, c) PDPP2FT-C₁₆, and d) PDPP2FT-2EH.

FIG. 15 shows the π-π stacking (black) and lamellar spacing (gray) correlation lengths for PDPP2FT derivatives in thin-film. Power conversion efficiency in devices is shown (blue diamond) to demonstrate the relationship between π-π stacking correlation length and device performance.

FIG. 16 shows the UV-Vis absorption spectra of PDPP2FT derivatives.

FIG. 17 shows the average J-V curve for solar cells fabricated from PDPP2FT-2BO.

FIG. 18 shows the GIXS scattering profile of a neat film of PDPP2FT-2BO.

FIG. 19 shows the GIXS scattering profiles of blend (BHJ) films of a) PDPP2FT-C₁₂, b) PDPP2FT-C₁₄, c) PDPP2FT-C₁₆, d) PDPP2FT-2EH, and e) PDPP2FT-2BO.

### DETAILED DESCRIPTION OF THE INVENTION

Before the invention is described in detail, it is to be understood that, unless otherwise indicated, this invention is not limited to particular sequences, expression vectors, enzymes, host microorganisms, or processes, as such may vary. It is also to be understood that the terminology used herein is for purposes of describing particular embodiments only, and is not intended to be limiting.

As used in the specification and the appended claims, the singular forms “a,” “an,” and “the” include plural referents unless the context clearly dictates otherwise. Thus, for example, reference to a “polymer” includes a single polymer molecule as well as a plurality of polymer molecules, either the same (e.g., the same molecule) or different.

In this specification and in the claims that follow, reference will be made to a number of terms that shall be defined to have the following meanings:

The terms “optional” or “optionally” as used herein mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

In some embodiments, the polymer of the present invention comprises the following chemical structure:

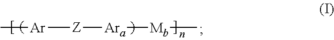

wherein Z is:

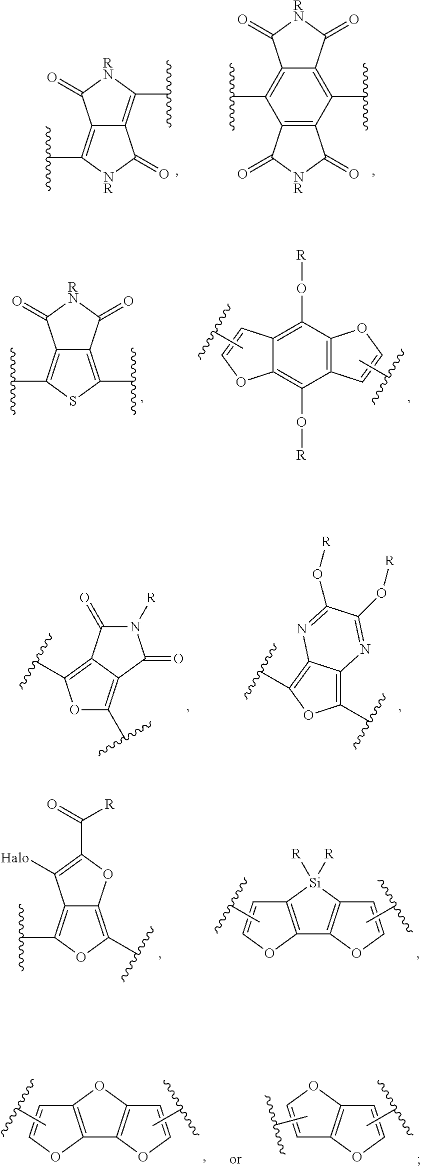

wherein each R is independently selected from hydrogen, an optionally substituted hydrocarbon, and a hetero-containing group, each Ar is independently selected from optionally substituted aryl and heteroaryl groups, each M is an optional, conjugated moiety, a represents a number that is at least 1, b represents a number from 0 to 20, n represents a number that is greater than 1, Halo is a halogen (such as F, Cl, Br, or I), and at least one Ar or M is a furan. The definition of Ar and M are found in U.S. Patent Application Pub. No. 2009/0065878 (incorporated herein by reference). In some embodiments, a is 1 and b is 1. In some embodiments, n is a number greater than 1. In some embodiments, Ar is a furan. In some embodiments, M is a furan. In some embodiments, a is 1, b is 1, and at least one Ar or M is a furan.

In some embodiments, the polymer comprises the following chemical structure:

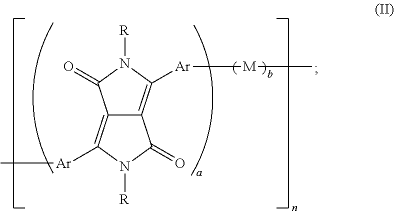

wherein each R is independently selected from hydrogen, an optionally substituted hydrocarbon, and a hetero-containing group, each Ar is independently selected from optionally substituted aryl and heteroaryl groups, each M is an optional, conjugated moiety, a represents a number that is at least 1, b represents a number from 0 to 20, n represents a number that is greater than 1, and at least one Ar or M is a furan. Certain polymers having chemical structure (II) are disclosed by U.S. Patent Application Pub. No. 2009/0065878 (incorporated herein by reference). In some embodiments, a is 1 and b is 1. In some embodiments, Ar is a furan. In some embodiments, M is a furan. In some embodiments, a is 1, b is 1, and at least one Ar or M is a furan.

In some embodiments, the polymer comprises the following chemical structure:

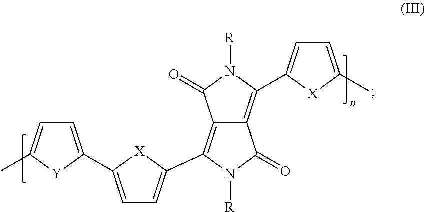

wherein each R is independently selected from hydrogen, an optionally substituted hydrocarbon, and a hetero-containing group, n represents a number that greater than 1, each X is independently O or S, Y is O or S, and at least one X or Y is O.

In some embodiments, the polymer comprises the following chemical structure:

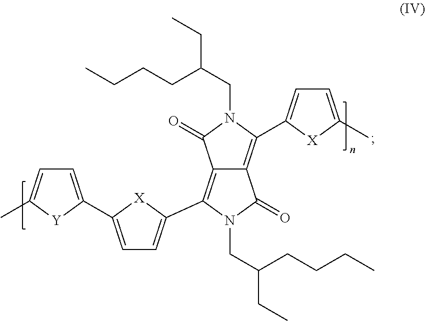

wherein n represents a number that greater than 1, X and Y are independently O or S, and at least one X or Y is O. In some embodiments, X is O. In some embodiments, Y is O. In some embodiments, X is S. In some embodiments, Y is S. In some embodiments, X is O and Y is S, wherein the polymer is PDPP2FT. In some embodiments, X is O and Y is O, wherein the polymer is PDPP3F.

In some embodiments, each R independently comprises an independently straight or branched alkyl chain. In some embodiments, each R independently comprises at least about 4, 5, 6, or 8 carbon atoms. In some embodiments, each R independently comprises from about 4 to 40 carbon atoms. In some embodiments, each R independently comprises from about 8 to 20 carbon atoms. In some embodiments, each R independently comprises at least 1 or 2 branch chains comprising from about 1 to 16 carbon atoms. In some embodiments, each R independently comprises at least 1 or 2 branch chains comprising from about 2 to 8 carbon atoms. In some embodiments, each R independently comprises a main chain of from 3 to 24 carbon atoms and a branch chain having 1 to 16 atoms. In some embodiments, each R independently comprises a main chain of from 3 to 24 carbon atoms and a branch chain having 2 to 8 atoms. In some embodiments, each R independently comprises a main chain of from 6 to 12 carbon atoms and a branch chain having 2 to 8 atoms. In some embodiments, each R independently comprises a branch chain attached to C2 of a main chain. In some embodiments, each R independently comprises a branch chain having 1, 2, 3, or 4 carbon atoms less than a main chain. In some embodiments, each R independently comprises a branch chain attached to C2 of a main chain, and the branch chain has 4 carbon atoms less than the main chain. In some embodiments, each R independently comprises 2-ethylhexyl (2EH), 2-butyloctyl (2BO), 2-hexylddecyl (2HD), or 2-octyldodecyl (2OD). In some embodiments, each R is octyl, decyl, dodecyl, tetradecyl, or hexadecyl. In some embodiments, where each monomer of the polymer has two R's, the R's are identical to each other.

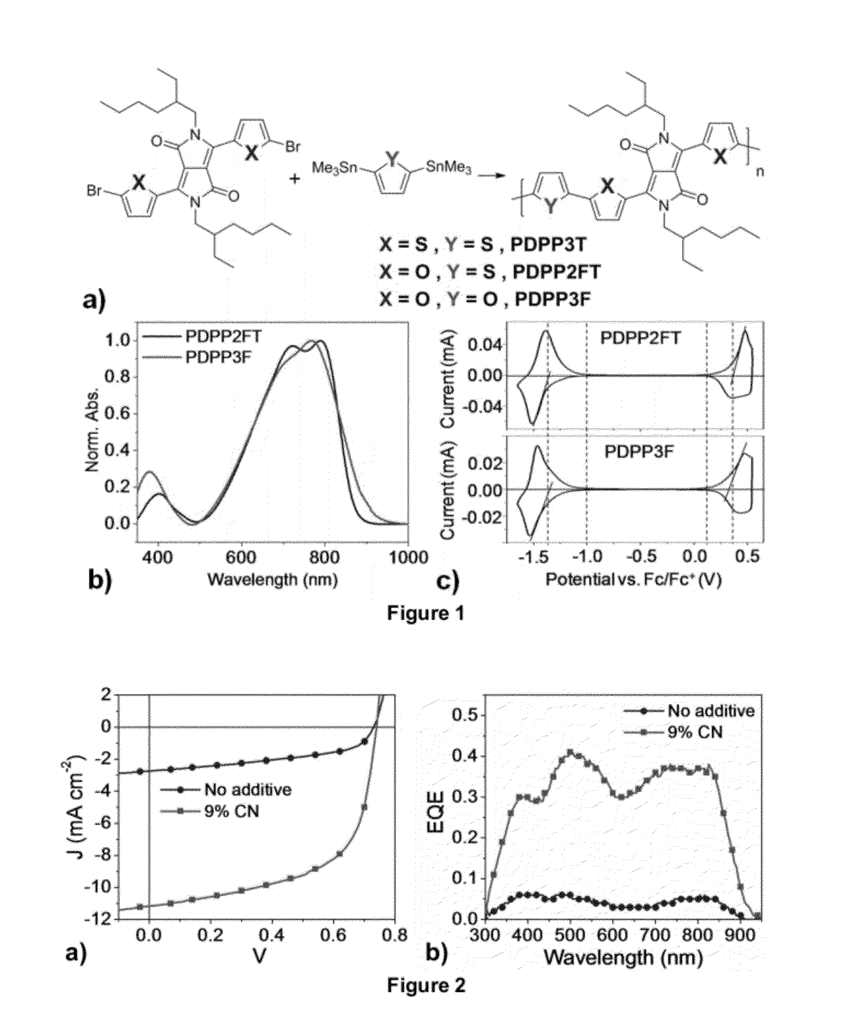

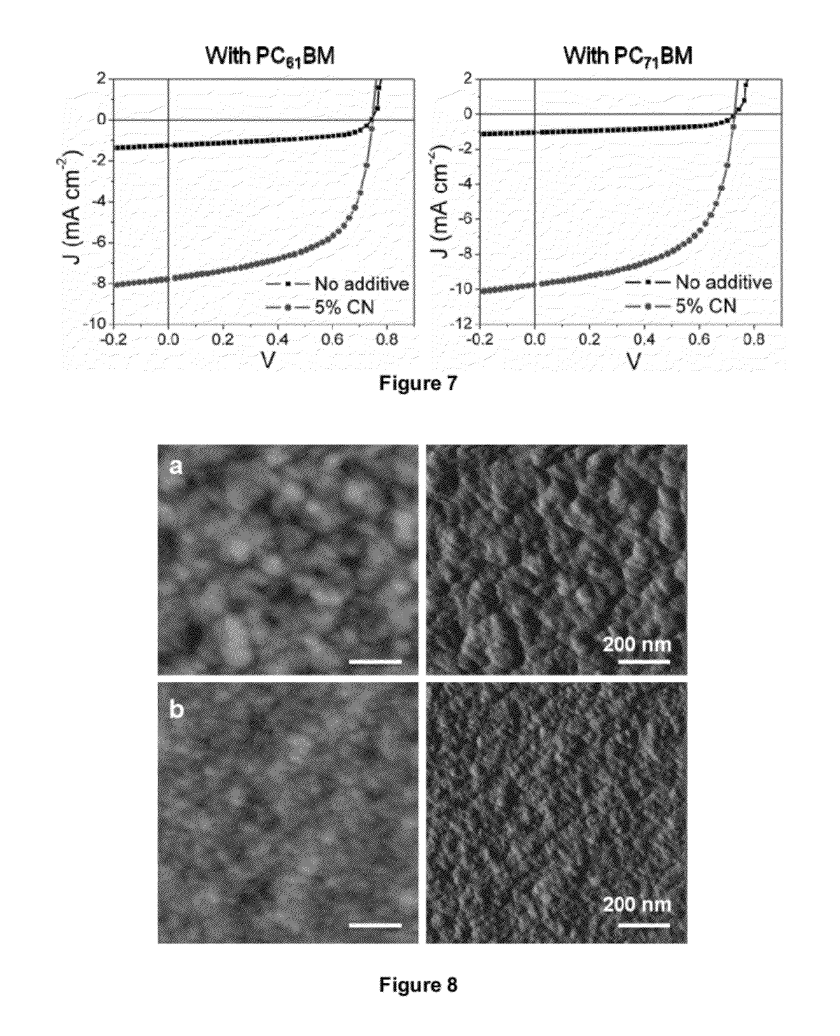

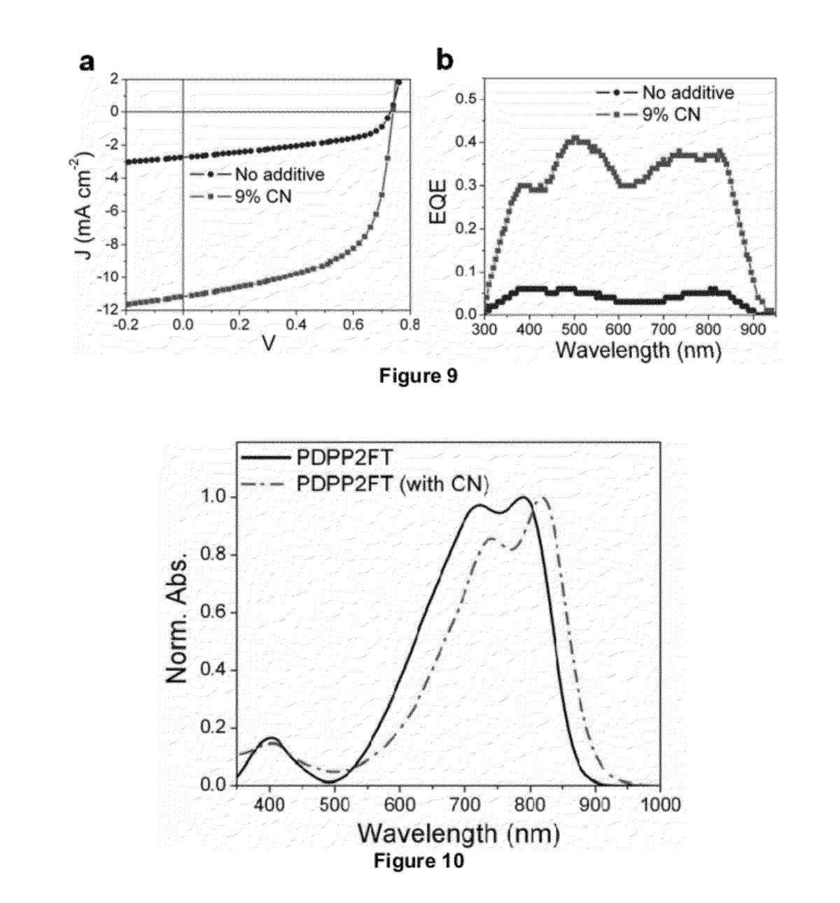

This invention provides for narrow band gap π-conjugated polymer backbones incorporating furans (such as PDPP2FT and PDPP3F, see FIG. 1a) and demonstrating photovoltaic efficiencies on the order of those obtained with their all-thiophene analogs (approaching 5%, see FIG. 9). The furan-containing semiconducting backbones were synthesized following the donor-acceptor methodology succinctly described above. The resulting polymers are solution-processable (i.e. can be spin-coated, spray-cast, ink-jet printed or stamped for example), stable to ambient oxidative processes, and possess absorption spectra extending into the near-IR (in turn addressing the spectral requirements for photovoltaic applications); see FIG. 1b. In particular, we found that furans can be employed to dramatically reduce the amount of aliphatic side-chain material necessary to solubilize the polymer backbones that otherwise require the presence of long and bulky substituents (i.e. insulating material typically hindering charge transport and device performance). The ca. 4% efficiency achieved with the all-furan low band gap polymer (PDPP3F, see FIG. 7) clearly demonstrates that the presence of thiophene in π-conjugated backbones is not essential to achieving high organic solar cell performance, and this critical result paves the path for the design and large-scale synthesis of organic electronic materials from sustainable synthetic resources. We expect that these findings are not limited to the backbones designed and synthesized herein as proof of concept, but will have critical implications on the design and synthesis of organic electronics in general, and of organic photovoltaics in particular. Chart 2 illustrates a number of furan-derivatized building units (donors in red, acceptors in blue) that could advantageously replace the thiophene-based analogs to produce high-performing photovoltaic polymers for device applications. High-performance furan-based photovoltaic polymers that can be synthesized from naturally occurring resources including sugars promise to impact the development of organic solar cells by providing a sustainable and environmentally benign alternative to thiophene- and selenophene-based organic semiconductors.

The invention also provides for furan-based π-conjugated polymers that could be used as the p-type component (i.e. electron-donor) with n-type components (i.e. electron-acceptor) other than fullerenes, including inorganic nanocrystals (e.g. CdSe, CdS, PbSe, PbS), n-dopable organometallic complexes, n-dopable small molecules and polymers.

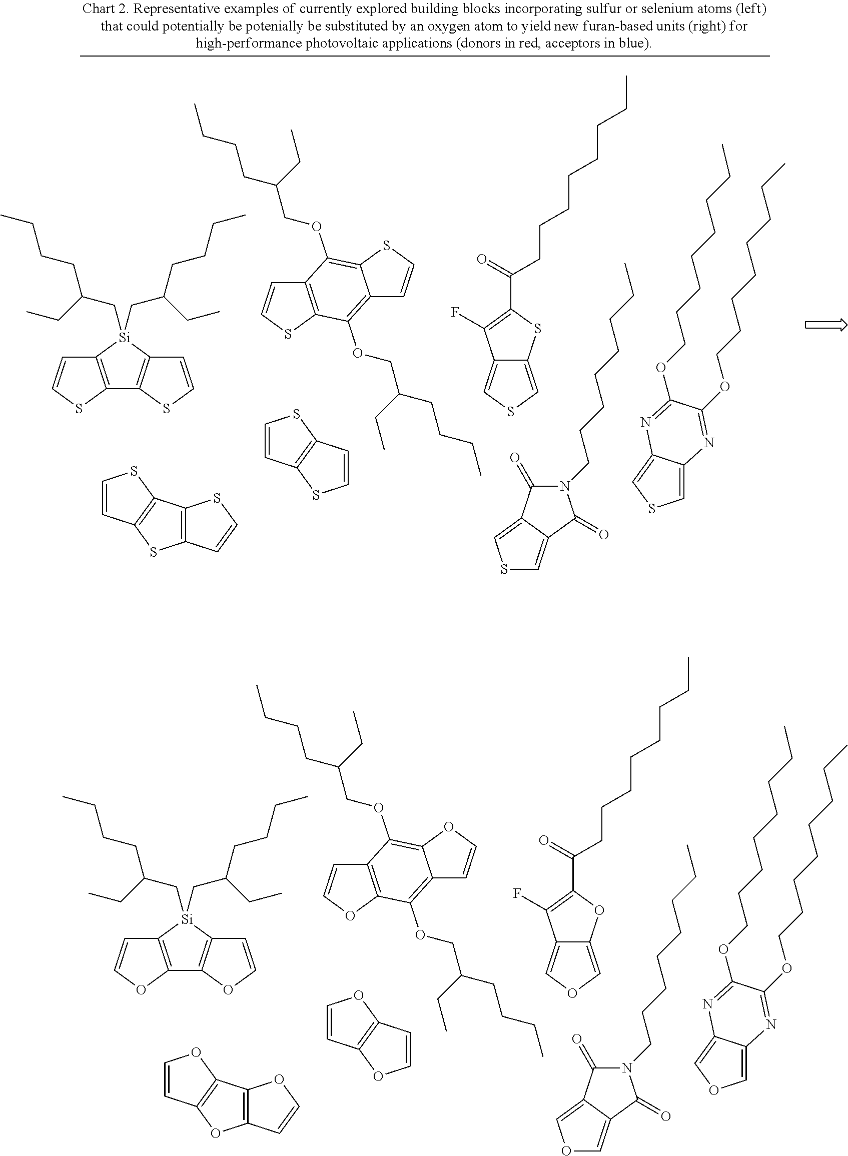

Furan heterocycles can be advantageously incorporated into conjugated polymer backbones without hindering their photovoltaic device performance. In addition, we show that furans can be employed to dramatically reduce the amount of aliphatic side-chain material necessary to solubilize polymer backbones that otherwise require the presence of long and bulky substituents. This concept is exemplified by the synthesis and characterization of two furan-containing semiconducting polymers: PDPP2FT and PDPP3F (see FIG. 1a). These polymers contain a diketopyrrolopyrrole (DPP) unit and are analogous to the low band gap polymer PDPP3T previously reported by Bijleveld, J. C., Zoombelt, A. P., Mathijssen, S. G. J., Wienk, M. M., Turbiez, M., de Leeuw, D. M. & Janssen, R. A. J. (Poly(diketopyrrolopyrrole-terthiophene) for Ambipolar Logic and Photovoltaics. J. Am. Chem. Soc. 131, 16616-16617 (2009)). Importantly, these furan-containing derivatives were synthesized with 2-ethylhexyl substituents whereas PDPP3T (as reported by Bijleveld et al., 2009) was appended with longer 2-hexyldecyl solubilizing groups.

A survey of state-of-the-art organic solar cells reveals that most high performance polymers reported so far rely on thiophene or thiophene-based heterocycles. The manufacturing of thiophene precursors involves the use of relatively toxic and environmentally harmful sulfur sources (e.g. carbon disulfide CS₂, phosphorus decasulfide P₄S₁₀, phosphorus heptasulfide P₄S₇, Lawesson's reagent, S₈). Selenium is an alternative to thiophene, but the particularly high level of toxicity of selenium sources and the resulting selenophene precursors have largely hindered the research and development of selenophene-based semiconducting organics so far. Based on these considerations, near-future large-scale industrial manufacturing of selenophene precursors is unlikely.

Furan and furan-based precursors can be made from a variety of natural products (e.g. corncobs, oat, wheat bran, sawdust, and more broadly by hydrolysis of polymers of sugar), and they can in turn be considered renewable and sustainable synthetic resources. The ability to mass-produce organic photovoltaics directly from non-toxic and environmentally harmless precursors could have a tremendous impact on the industrial development and long-term viability of this technology. Based on these considerations, furan-based photovoltaics could be anticipated to rapidly replace thiophene-based systems in mass-produced devices. It is also worth noting that in the case where the performance of furan-based photovoltaic polymers remains inferior to that of their all-thiophene analogs, the scalability and environmental sustainability of the furan-alternatives may ultimately prevail with respect to large-scale industrial manufacturing processes.

Furans can be advantageously used as alternatives to thiophenes and thiophene-based building units in the design and synthesis of low band gap conjugated polymers with efficient solar cell performance. The polymers examined in Example 1 herein (PDPP2FT and PDDP3F) exhibit near-identical optical and electronic properties, and demonstrate power conversion efficiencies approaching 5% in solar cell devices with fullerenes. In particular, the ca. 4% efficiency achieved with the all-furan low band gap polymer PDPP3F clearly demonstrates that the presence of thiophene in π-conjugated backbones is not essential to achieve high performance, and this critical result paves the path for the design and large-scale synthesis of organic electronic materials from sustainable synthetic resources. In addition, the insertion of furan within the conjugated backbone allows for shorter solubilizing groups to be used, compared to those required to solubilize the all-thiophene polymer PDPP3T. In particular, polymer solubility improves substantially when a combination of thiophene and furan heterocycles is incorporated, and we expect this critical finding to be applicable to the broad area of conjugated polymers for application in electronic devices including organic solar cells and transistors.

It is to be understood that, while the invention has been described in conjunction with the preferred specific embodiments thereof, the foregoing description is intended to illustrate and not limit the scope of the invention. Other aspects, advantages, and modifications within the scope of the invention will be apparent to those skilled in the art to which the invention pertains.

All patents, patent applications, and publications mentioned herein are hereby incorporated by reference in their entireties.

The invention having been described, the following examples are offered to illustrate the subject invention by way of illustration, not by way of limitation.

### Example 1

### Incorporation of Furan in Low Band Gap Polymers for Efficient Solar Cells

Polymer bulk heterojunction (BHJ) solar cells have attracted significant attention due to their potential for achieving large area, flexible photovoltaic devices through low-cost solution deposition techniques.^{1,2} Much of the recent research effort has focused on the development of low band gap donor polymers that have broad absorption spectra.³⁻⁵ The search for new building blocks for semiconducting polymers continues as we gain mechanistic understandings and establish design rules relevant to organic electronic applications.⁶⁻⁸ For example, the ideal polymer should (i) have sufficient energy level offsets with fullerenes for efficient charge separation while maximizing the open circuit voltage,^{8,9} (ii) display an absorption spectrum extending across the visible spectrum and into the near-IR, and (iii) maintain high extinction coefficients over this spectral range.⁶ At the same time, it has become increasingly apparent that a balance among the competing effects of solution processability, miscibility with the fullerene component, and solid state packing needs to be established.¹⁰⁻¹² Both the chemical structure of the backbone repeat units and the choice of the solubilizing side-chains critically impact the above-mentioned criteria.^{13,14} For example, while the use of longer and bulkier alkyl substituents improves solubility, it also increases lamellar and π-stacking distances, hindering intermolecular ordering, and affecting the transport of charge carriers across the polymer stacks.^{13,15,16} In this regard, strategies to reduce the length, bulkiness, and density of solubilizing side-chains along the conjugated polymer backbone are well worth exploring.

A survey of state-of-the-art BHJ solar cells reveals that most high performance polymers reported so far rely on thiophene or thiophene-based heterocycles.¹⁷⁻²³ While thiophene-based conjugated materials have attracted much attention in the area of organic electronics, only a limited number of studies have examined furan-containing materials potentially useful for device applications.²⁴⁻²⁶ Recently, furans have been used as an alternative to thiophenes in organic dyes for dye-sensitized solar cells and have shown very similar optical and electronic properties.^{27,28} Furan-based heterocycles have also been introduced as peripheral substituents in one of the highest performing small molecule photovoltaics.²⁹ The sparsity of studies examining polymer backbones containing furans in this field is surprising given that furans exhibit similar energy levels and a comparable degree of aromaticity relative to their thiophene counterparts.^{24,30} Importantly, furan derivatives can be synthesized from a variety of natural products, hence they fall into the category of renewable and sustainable synthetic resources.

In this contribution, we demonstrate that furan heterocycles can be advantageously incorporated into conjugated polymer backbones without hindering their photovoltaic device performance. In addition, we show that furans can be employed to dramatically reduce the amount of aliphatic side-chain material necessary to solubilize polymer backbones that otherwise require the presence of long and bulky substituents. This concept is exemplified by the synthesis and characterization of two furan-containing semiconducting polymers: PDPP2FT and PDPP3F (see FIG. 1a). These polymers contain a diketopyrrolopyrrole (DPP) unit^{22,31-33} and are structurally analogous to the low band gap polymer PDPP3T previously reported by Janssen et al.³⁴. Importantly, these furan-containing derivatives were synthesized with 2-ethylhexyl substituents whereas PDPP3T (as initially reported³⁴) was appended with 2-hexyldecyl solubilizing groups.

While exploring the use of furans as alternatives to thiophenes in low band gap conjugated polymers involving DPP, we found that soluble high molecular weight PDPP2FT could be readily obtained (Mₙ=66 kDa). The use of 2-ethylhexyl substituents was sufficient to impart PDPP2FT with appropriate solubility in common organic solvents (e.g. tetrahydrofuran, chloroform, chlorobenzene) for device fabrication. In contrast, the all-furan derivative PDPP3F synthesized using the same polymerization protocol (Mₙ=29 kDa, see SI) was found to possess slightly reduced solubility in the same organic solvents. While the improved solubility of oligofurans over oligothiophenes has been reported,³⁵ it appears that the ratio of furan to thiophene in mixed oligomers also impacts solubility.^{36,37} As a control experiment, we attempted to synthesize the 2-ethylhexyl substituted derivative of the all-thiophene PDPP3T following the same polymerization procedure as that used for PDPP2FT and PDPP3T. However, the polymerization yielded only low molecular weight fractions minimally soluble in all common organic solvents (Mₙ=2 kDa).

The onset of optical absorption of PDPP2FT in thin film was measured to be 880 nm (E_{g}=1.41 eV) while the λₘₐₓ was observed at 789 nm (See FIG. 1b), which is comparable to the optical properties of PDPP3T reported earlier by Janssen et al. (E_{g}=1.3 eV)³⁴. PDPP3F also possesses similar optical properties with E_{g}=1.35 eV and λₘₐₓ at 767 nm. FIG. 1c shows the cyclic voltammograms of the two polymers. The onsets of oxidation and reduction of PDPP2FT were observed at +0.28 and −1.34 V vs. Fc/Fc⁺, corresponding to HOMO and LUMO levels at −5.4 eV and −3.8 eV vs. vacuum. For PDPP3F, the onsets were observed at +0.35 and −1.34 V, corresponding to HOMO and LUMO levels at −5.5 and −3.8 eV. These values are comparable to those obtained for the low molecular weight all-thiophene analog PDPP3T.

Solar cells were fabricated using PDPP2FT as the electron donor and [6,6]-phenyl-C₆₁-butyric acid methyl ester (PC₆₁BM) as the electron acceptor with the device structure ITO/PEDOT:PSS/polymer:PCBM/LiF/Al. The active layers were spin-coated from chlorobenzene, and, in some cases, a small amount of the high boiling point additive 1-chloronaphthalene (CN) was added to optimize blend morphology for enhanced device performance. The J-V curves and external quantum efficiency (EQE) spectra of PDPP2FT:PC₆₁BM devices are described herein. Without any post-fabrication treatment, the PDPP2FT:PC₆₁BM device spin-coated from pure chlorobenzene afforded 3.4% power conversion efficiency (PCE) under AM 1.5 G, 100 mW cm⁻² illumination (see Table 1). The use of chlorobenzene containing 1 vol % 1-chloronaphthaleneobenzene for spin-coating led to a slight improvement to 3.7% PCE, mostly through an increase in the photocurrent. The best device was obtained from a blend of PDPP2FT:PC₆₁BM in a 1:3 weight ratio and gave a PCE of 3.8%, with an open circuit voltage (V_{oc}) of 0.76 V, a short-circuit current density (J_{sc}) of 9.0 mA cm⁻², and a fill factor (FF) of 55%. The EQE showed a sharp onset at the optical band gap of the polymer and reached a maximum value of 33%. For BHJ devices containing a 1:3 blend of PDPP3F:PC₆₁BM, chloroform was found to be a better solvent, and an average efficiency of 3.0% was achieved (see Table 2).

As an attempt to increase the breadth of the photoactive spectrum and the overall photocurrent, we fabricated solar cells with the more light-absorbing fullerene derivative PC₇₁BM. FIG. 2 shows the J-V curves and the EQE spectra of optimized devices fabricated from blends of PDPP2FT:PC₇₁BM at a 1:3 weight ratio in chlorobenzene. Interestingly, without any additive, the PC₇₁BM devices performed poorly with an average PCE of only 0.86%. However, with the addition of high boiling CN to the blend solution, device performance improved by more than fivefold with much higher J_{sc} and an average PCE of 4.7%. The best device was obtained with the addition of 9% CN by volume relative to chlorobenzene, and it achieved a V_{oc} of 0.74 V, a J_{sc} of 11.2 mA cm⁻², a FF of 60%, and a PCE of 5.0%, a result comparable to that obtained by Janssen et al. with PDPP3T³⁴. The J_{sc} value calculated from the integration of the EQE spectrum of the best device is 11.4 mA cm⁻², which closely matches the J_{sc} value obtained from the J-V measurement under white light illumination. Solar cells containing a blend of PDPP3F and PC₇₁BM were also fabricated and achieved an average PCE of 3.8% (max 4.1%) after optimization. Here again, the device performance was <1% without the addition of CN. These device results strongly support the potential of furan-based polymeric systems in organic photovoltaic devices.

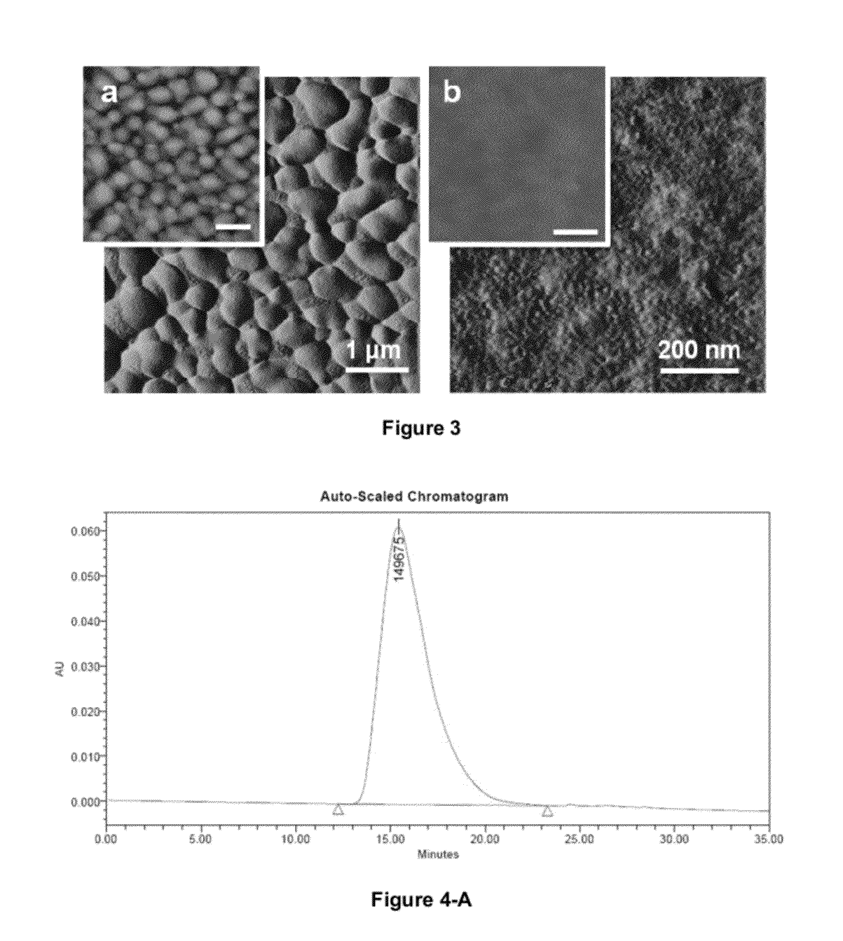

The dramatic difference in device performance with and without the CN additive is most likely due to the optimization of blend morphology. FIG. 3 compares the atomic force microscopy (AFM) images of blend films of PDPP2FT:PC₇₁BM at the optimized ratio. The blend without additive exhibits coarse phase separation between the polymer and PC₇₁BM with large micron-sized domains. In contrast, the addition of CN led to much finer phase separation between the two materials and the formation of fiber-like interpenetrating morphologies at the length scale of ˜20 nm, which is close to the ideal domain size assuming an exciton diffusion length of 5-10 nm.³⁸⁻⁴⁰ The thin film absorption of PDPP2FT also redshifts and displays more distinct vibronic structures when CN is added to the solution before spin-coating. The redshift in absorption is indicative of increased intermolecular ordering and planarity in the polymer backbone and could be another reason for the improved performance of devices fabricated with CN.

Methods and Materials: All reagents from commercial sources were used without further purification, unless otherwise noted. Flash chromatography was performed using Silicycle SiliaFlash® P60 (particle size 40-63 μm, 230-400 mesh) silica gel. Dimethylformamide (DMF) and Tetrahydrofuran (THF) were purchased from Fisher Scientific, and each was purified by passing it under N₂ pressure through two packed columns of neutral alumina. All compounds were characterized by ¹H NMR (400 MHz) and ¹³C NMR (100 MHz) on a Bruker AVB-400 or AVQ-400 instrument. All NMR spectra were acquired at room temperature unless otherwise noted. Data from high-resolution mass spectrometry (HRMS) using electron impact (EI) were obtained by the UC Berkeley mass spectrometry facility. Matrix assisted laser desorption/ionization mass spectrometry (MALDI-TOF MS) was performed on a PerSeptive Biosystems Voyager-DE using 2,2′:5′,2″-terthiophene as the matrix. Samples were prepared by diluting the monomers in chloroform with the matrix. For polymer molecular weight determination, polymer samples were dissolved in HPLC grade chloroform at a concentration of 1 mg/ml, briefly heated and then allowed to return to room temperature prior to filtering through a 0.2 μm PVDF filter. SEC was performed using HPLC grade chloroform at a flow rate of 1.0 mL/min on two 300×8 mm linear S SDV, 5 μm columns (Polymer Standards Services, USA Inc.) at 30° C. using a Waters (Milford, Mass.) separation module and a Waters 486 Tunable Absorption Detector monitored at 254 nm. The instrument was calibrated vs. polystyrene standards (580-96,000 Da) and data was analyzed using Millenium 3.2 software.

Synthetic Procedures:

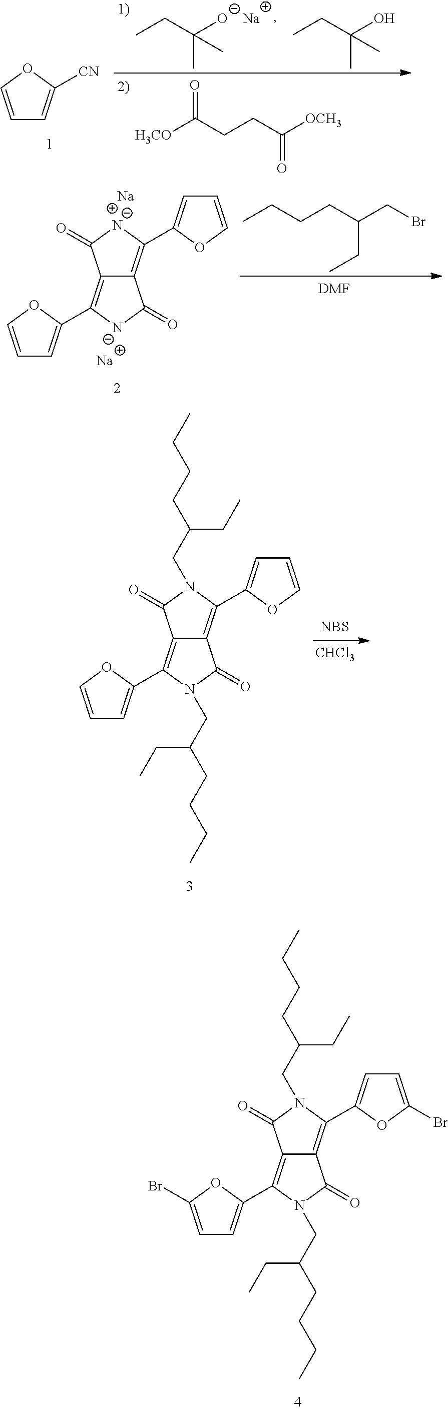

3,6-di(furan-2-yl)pyrrolo[3,4-c]pyrrole-1,4(2H,5H)-dione (2): A 500 mL three-neck round-bottom flask connected to a condenser and dry nitrogen flow was charged with a stir bar and tert-amyl alcohol (250 mL). Sodium metal pieces (2.47 g, 107 mmol) were progressively added to the warmed solution of tert-amyl alcohol (60-70° C.). After complete addition of the sodium, the temperature was progressively raised to 120° C. The mixture was stirred overnight at 120° C. Furan-2-carbonitrile (1) (10.0 g, 107 mmol) was subsequently added to the hot mixture of sodium alkoxide. Dimethyl succinate (5.23 g, 35.8 mmol) was then added dropwise over a period of 20 min (the reaction mixture turned dark orange-red), and the resulting mixture was stirred for 1.5 h. The reaction mixture was then cooled to room temperature, and the precipitated sodium salt 2 was filtered over a Buchner funnel for collection and dried under vacuum (14.7 g, 87% yield). Compound 2 was used without further purification.

2,5-bis(2-ethylhexyl)-3,6-di(furan-2-yl)pyrrolo[3,4-c]pyrrole-1,4(2H,5H)-dione (3): Compound 2 (3.36 g, 10.8 mmol) and 100 mL of dry DMF were added to a 250 mL two-neck round-bottom flask, equipped with a condenser and stir-bar and placed under N₂ atmosphere. The mixture was heated to 120° C., stirred for 30 min, and 2-ethylhexylbromide (6.05 g, 31.3 mmol) was then added quickly (while at 120° C.). The reaction mixture was subsequently stirred at 140° C. for ca. 6 h, and cooled to room temperature. The organic phase was extracted with diethyl ether and washed with water. The diethyl ether was evaporated, and the resulting tacky solid (red) was purified by column chromatography using CHCl₃ as eluent. 1.30 g of 3 were isolated (25% yield). ¹H NMR (400 MHz, CDCl₃): δ (ppm)=8.33 (d, J=3.6 Hz, 2H), 7.61 (d, J=1.3 Hz, 2H), 6.69 (dd, J=1.7 Hz, 3.6 Hz, 2H), 4.04 (d, J=7.8 Hz, 4H), 1.80-1.68 (m, 2H), 1.39-1.26 (m, 16H), 0.95-0.85 (m, 12H). ¹³C (100 MHz, CDCl₃): δ (ppm)=161.4, 145.0, 144.8, 134.1, 120.4, 113.6, 106.6, 46.3, 40.1, 30.7, 28.8, 24.0, 23.2, 14.2, 10.9. MALDI-TOF MS (m/z): calc'd for C₃₀H₄₀N₂O₄ [M⁺]=492.3; found 492.9.

3,6-bis(5-bromofuran-2-yl)-2,5-bis(2-ethylhexyl)pyrrolo[3,4-c]pyrrole-1,4(2H,5H)-dione (4): Compound 3 (1.01 g, 2.05 mmol) was charged in a 100 mL single-neck round-bottom flask filled with 50 mL of CHCl₃. The mixture was cooled to 0° C. and stirred while N-bromosuccinimide (NBS) was added in small portions. The mixture was allowed to warm to room temperature and stirred for 2 h following complete addition of NBS. The organic phase was extracted with CHCl₃ and washed with water. The CHCl₃ was evaporated, and the resulting tacky solid (dark red) was purified by column chromatography using CHCl₃ as eluent. 0.95 g of 4 were isolated (71% yield). ¹H NMR (400 MHz, CDCl₃): δ (ppm)=8.30 (d, J=3.7 Hz, 2H), 6.62 (d, J=3.7 Hz, 2H), 3.99 (add, J=2.7 Hz, 7.4 Hz, 4H), 1.78-1.68 (m, 2H), 1.39-1.24 (m, 16H), 0.92 (t, J=7.5 Hz, 6H), 0.88 (t, J=7.0 Hz, 6H). ¹³C (100 MHz, CDCl₃): δ (ppm)=161.1, 146.4, 132.9, 126.4, 122.4, 115.7, 106.4, 46.4, 40.2, 30.7, 28.9, 23.9, 23.3, 14.2, 10.8. MALDI-TOF MS (m/z): calc'd for C₃₀H₃₈Br₂N₂O₄ [M⁺]=648.1; found 648.3.

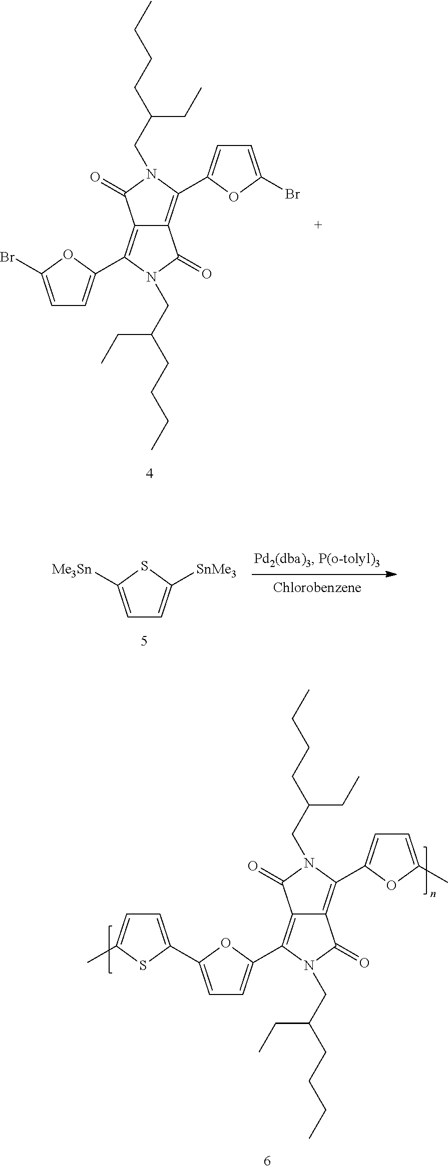

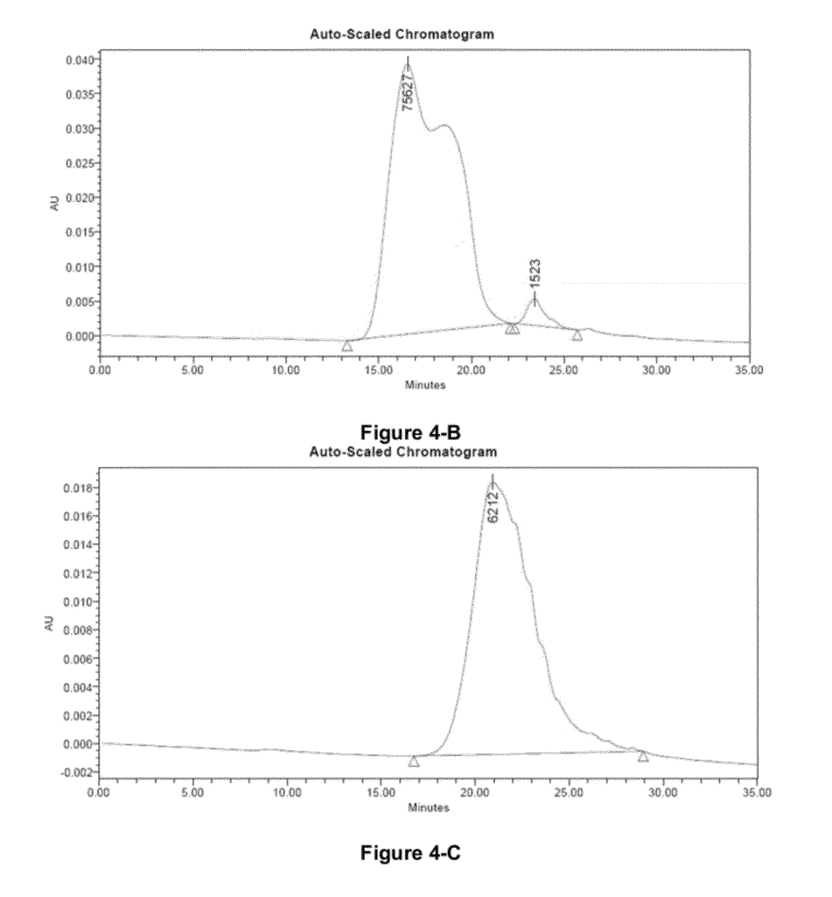

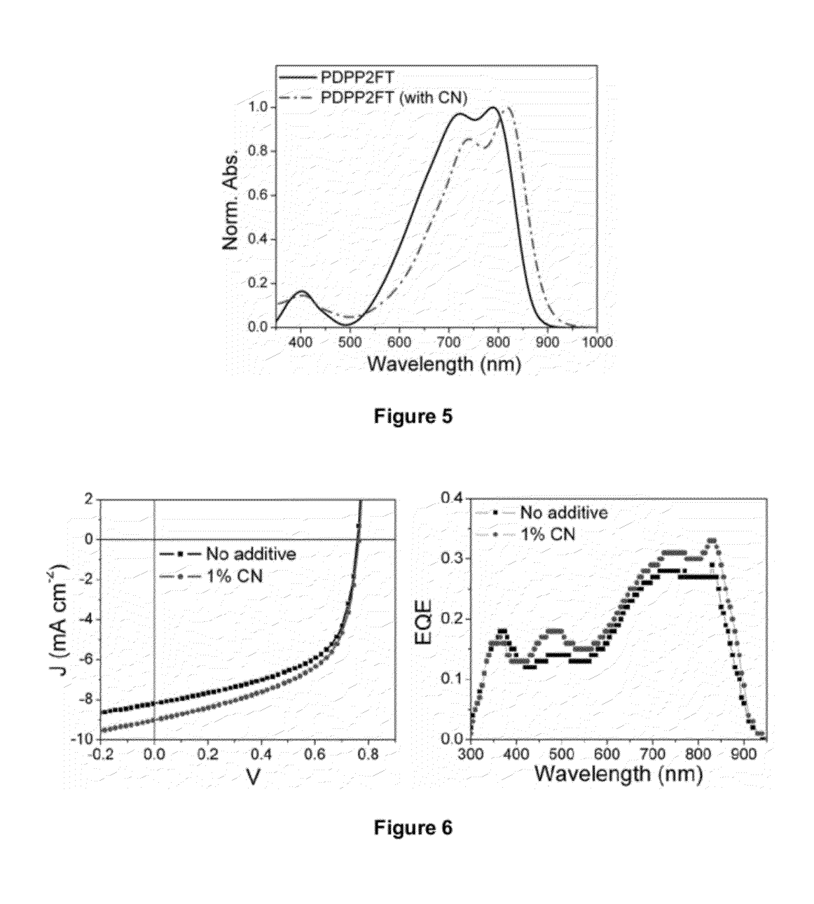

PDPP2FT (6): 4 (200 mg, 0.307 mmol), 2,5-bis(trimethylstannyl)-thiophene (5) (126 mg, 0.307 mmol), Pd₂(dba)₃ (2 mol %) and P(o-tol)₃ (8 mol %) were charged with a 50 mL Schlenk tube, cycled with N₂ and subsequently dissolved in 6 mL of degassed chlorobenzene. The mixture was stirred for 24 h at 110° C. The reaction mixture was allowed to cool to 55° C., 15 mL of CHCl₃ was added, and the strongly complexing ligand N,N-diethylphenylazothioformamide (CAS#39484-81-6) was subsequently added (as a palladium scavenger). The resulting mixture was stirred for 1 h at 55° C., and precipitated into methanol (200 mL). The precipitate was filtered through a Soxhlet thimble and purified via Soxhlet extraction for 12 h with methanol and 1 h with hexanes, followed by collection in chloroform. The chloroform solution was then passed through a plug of silica, neutral alumina, and celite (1:1:1), concentrated by evaporation and precipitated into methanol (200 mL). The polymer 6 was filtered off as a dark solid (162 mg). SEC analysis: Mₙ=66 kDa, PDI=2.05 (See FIG. 4-A).

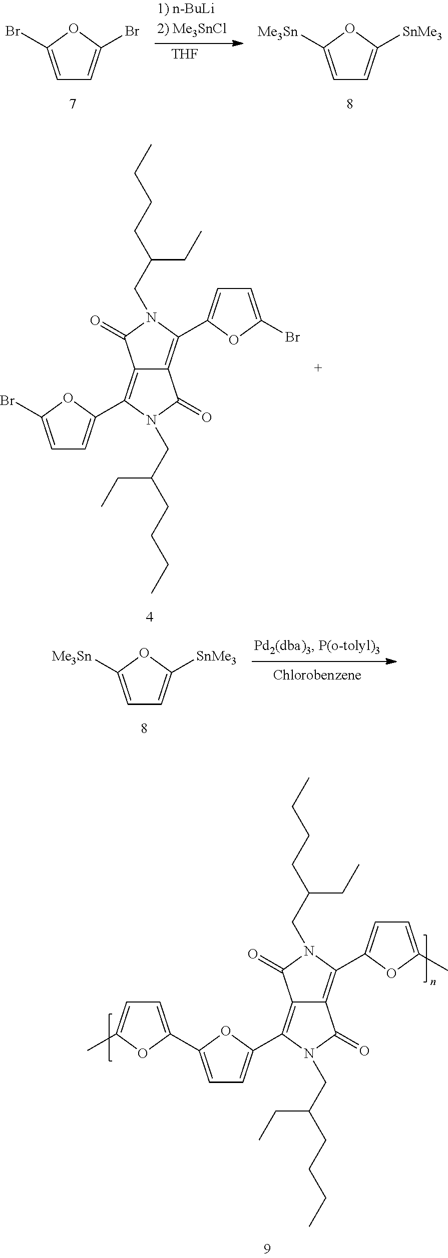

2,5-bis(trimethylstannyl)furan (8): Compound 7 (2.0 g, 8.85 mmol) and 30 mL of dry THF were added to a 100 mL two-neck round-bottom flask with stir bar, and placed under N₂ atmosphere. The mixture was cooled to −78° C., and n-BuLi (2.5 M in hexanes) (18.2 mmol, 7.4 mL) was added dropwise over 30 min (while at −78° C.). Following complete addition of n-BuLi, the reaction mixture was stirred for an additional 15 min at −78° C. It was subsequently allowed to reach room temperature and stirred for 1 h. The reaction mixture was cooled down to −78° C., Me₃SnCl (18.6 mmol, 3.70 g) was charged all at once, and the mixture was stirred at −78° C. for 15 min. It was then allowed to reach room temperature and stirred for 12 h. The organic phase was extracted with diethyl ether and washed with water. Diethyl ether was evaporated, and the resulting oil (yellow) was passed through a plug of basic alumina using hexanes as eluent. Hexanes were evaporated, and the resulting oil (colorless) was distilled under reduced pressure (68-72° C. at 180 mTorr) and 0.74 g of 8 were isolated (21% yield). ¹H NMR (400 MHz, CDCl₃): δ (ppm)=6.71 (s, 2H), 0.40 (m, 18H). ¹³C (100 MHz, CDCl₃): δ (ppm)=165.2, 120.3, −9.0.

PDPP3F (9): The same polymerization and purification protocols as those described for PDPP2FT (6) were followed. Polymer 9 was collected as a dark and brittle solid (58 mg). SEC analysis: Mₙ=29 kDa, PDI=2.02 (See FIG. 4-B).

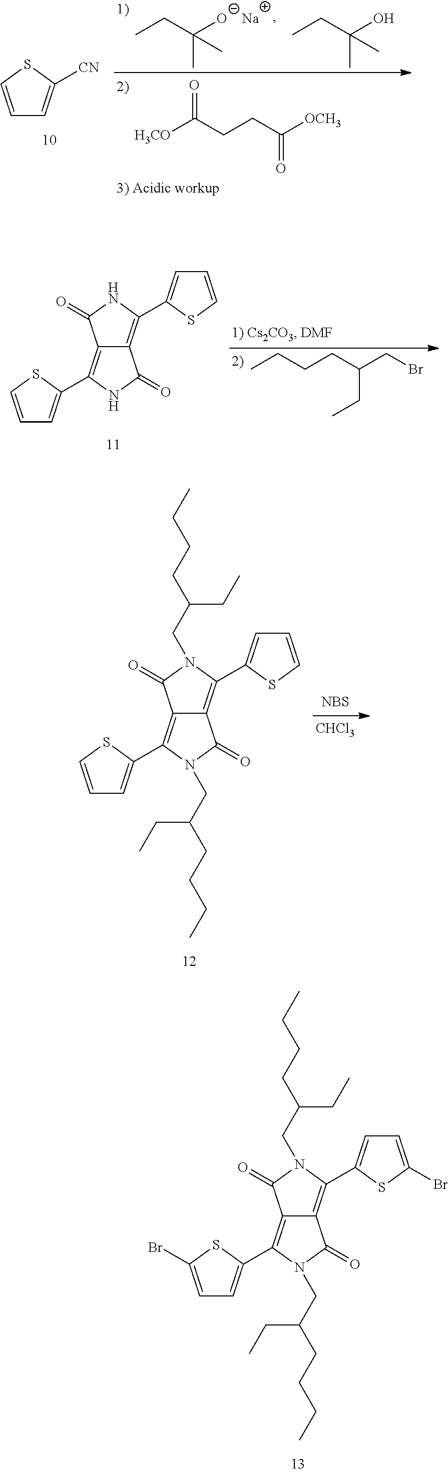

3,6-di(thien-2-yl)pyrrolo[3,4-c]pyrrole-1,4(2H,5H)-dione (11). A 500 mL three-neck flask connected to a condenser was charged with a stir bar and tert-amyl alcohol (250 mL). Sodium metal (2.56 g, 108 mmol) immersed in mineral oil was thoroughly washed with hexanes and cut into small pieces. The sodium metal pieces were slowly added to the reaction mixture over a 1.5 h period while the temperature was slowly increased to 120° C. over the same amount of time. After all the sodium metal pieces were dissolved, compound 10 (11.9 g, 108 mmol) was added to the reaction. As dimethyl succinate (5.29 g, 36.2 mmol) was added dropwise to the reaction mixture over 1 h, the solution turned dark red. The reaction contents were stirred at 120° C. for 2 h, and then precipitated into acidic MeOH (400 mL MeOH and 20 mL conc. HCl). Filtration of the suspension through a Buchner funnel yielded 11 as a dark red solid (9.10 g), which was used in subsequent reactions without further purification (83% yield).

2,5-bis(2-ethylhexyl)-3,6-di(thien-2-yl)pyrrolo[3,4-c]pyrrole-1,4(2H,5H)-dione (12). A 250 mL of round bottom flask was charged with 11 (4.50 g, 15.0 mmol), cesium carbonate (14.6 g, 45.0 mmol) and dry DMF (150 mL). The reaction contents were stirred at 120° C. for 3 h before 2-ethylhexyl bromide (7.24 g, 37.5 mmol) was added to the mixture. After the reaction mixture was heated at 130° C. for 20 h, it was filtered through qualitative filter paper into a 500 mL round-bottom flask to remove salt byproducts. The solvent was removed from the crude product under reduced pressure. The crude material was purified by flash chromatography (CHCl₃) to yield 1.24 g of 12 as a dark red-purple tacky solid (16% yield). ¹H NMR (400 MHz, CDCl₃): δ=8.89 (d, J=3.9 Hz, 2H), 7.61 (d, J=5.0 Hz, 2H), 7.25 (at, J=4.5 Hz, 1H), 4.01 (m, 4H), 1.92-1.78 (m, 2H), 1.40-1.18 (m, 16H), 0.89-0.83 (adt, J=7.3 Hz, 8.8 Hz, 12H). ¹³C (100 MHz, CDCl₃): δ=161.8, 140.5, 135.4, 130.6, 130.0, 128.5, 108.0, 45.9, 39.2, 30.3, 28.4, 23.6, 23.2, 14.1, 10.6. HRMS (EI, m/z) calc'd for C₃₀H₄₀N₂O₂S₂ [M]⁺: 524.2531; found: 524.2535.

3,6-bis(5-bromothien-2-yl)-2,5-bis(2-ethylhexyl)pyrrolo[3,4-c]pyrrole-1,4(2H,5H)-dione (13). A 100 mL single-neck round-bottom flask was charged with a stir bar, 8 (1.21 g, 2.31 mmol) and chloroform (23 mL) under ambient conditions. After the reaction mixture was stirred in an ice bath at 0° C. for 20 min, NBS (821 mg, 4.61 mmol) was added in small portions over 30 min. After stirring for another 20 min, the reaction mixture was washed with water. The organic extract was dried over MgSO₄, and solvent was removed under reduced pressure. Purification by flash chromatography (20% hexanes in CHCl₃) yielded 1.30 g of a purple solid (83%). ¹H NMR (400 MHz, CDCl₃): δ=8.64 (d, J=4.2 Hz, 2H), 7.22 (d, J=4.2 Hz, 2H), 3.92 (m, 4H), 1.88-1.78 (m, 2H), 1.39-1.19 (m, 16H), 0.90-0.84 (aq, J=7.3 Hz, 12H). ¹³C (100 MHz, CDCl₃): δ=161.5, 139.5, 135.5, 131.6, 131.3, 119.2, 108.1, 46.1, 39.2, 30.3, 28.4, 23.7, 23.2, 14.2, 10.6. HRMS (EI, m/z) calc'd for C₃₀H₃₈Br₂N₂O₂S₂ [M]⁺: 682.0721; found: 682.0733.

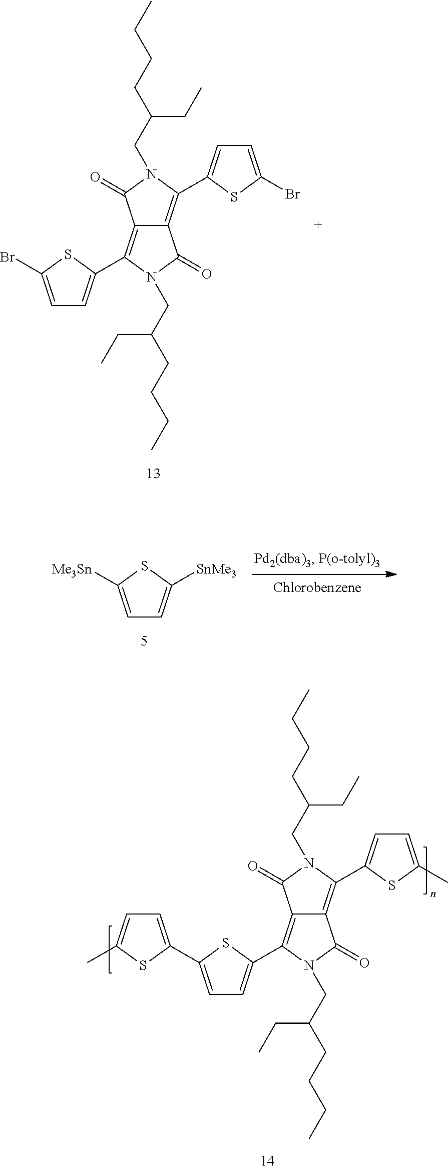

PDPP3T (14): The same polymerization protocol as that described for PDPP2FT (6) was followed. The substantial solubility limitations encountered with 14 during the purification process (initially attempted as described for PDPP2FT (6)) led us to establish the following modified protocol for the basic characterization of 14: on a second polymerization, after 24 h, the reaction was cooled to room temperature and aliquots were taken for SEC and CV analysis (˜1 mL was extracted from the reaction mixture and precipitated into ˜3 mL of methanol). The crude polymer 14 was collected and dried under nitrogen flow before further use. SEC analysis of the soluble fraction of 14: Mₙ=2 kDa, PDI=2.71 (See FIG. 4-C).

Device Fabrication: All photovoltaic devices have a layered structure with the photoactive layer sandwiched between the two electrodes, ITO and LiF/Al. Glass substrates coated with a 150 nm sputtered ITO pattern of 20Ω□⁻¹ resistivity were obtained from Thin Film Devices Inc. The ITO-coated glass substrates were ultrasonicated for 20 min each in 2% Hellmanex soap water, DI water, acetone, and then isopropanol. The substrates were dried under a stream of dry nitrogen and then underwent UV-ozone treatment for 5 min. A dispersion of PEDOT:PSS (Baytron PH) in water was filtered (0.45 μm PVDF) and spin coated at 4000 RPM for 60 s, affording a ca. 40 nm layer. The substrates were dried for 10 min at 140° C. in air and then transferred into a nitrogen glove box for subsequent procedures. PDPP2FT solutions were prepared in chlorobenzene at a concentration of 15 mg/ml and were heated to 100° C. and stirred overnight for complete dissolution. PDPP2FT solutions were mixed with 30 mg/ml filtered PC₆₁BM or PC₇₁BM (Nano-C) solutions to yield blend solutions of different concentrations and weight ratios of polymer to PCBM. PDPP3F solutions were prepared in chloroform at a concentration of 10 mg/ml and were heated to 50° C. and stirred overnight for complete dissolution. PDPP3F solutions were mixed with 20 mg/ml filtered PC₆₁BM or PC₇₁BM solutions in chloroform to yield blend solutions of different concentrations and weight ratios of polymer to PCBM. Varying amounts of additive CN were added to the blend solutions before spin coating. The active layers of all devices were spin coated at 2000 RPM for 50 s on top of the PEDOT:PSS layer. The substrates were then placed in an evaporation chamber and pumped down to a pressure of ˜6×10⁻⁷ Torr before evaporating a 1 nm LiF layer and subsequently a 100 nm Al layer through a shadow mask on top of the photoactive layer to yield devices with active areas of 0.03 cm⁻². The mechanical removal of part of the organic layer allowed contact with the ITO and adding conductive Ag paste to the removed area to ensure electrical contact completed the device. Testing of the devices was performed under a nitrogen atmosphere with an Oriel Xenon arc lamp having an AM 1.5 G solar filter to yield 100 mW cm⁻² light intensity as calibrated by an NREL certified silicon photocell. Current-voltage behavior was measured with a Keithley 2400 SMU. During the device optimization process, various parameters (solution concentration, blends ratio, spin speed, additive percentage) were tested and more than 200 devices were tested and optimized conditions were repeated to ensure reproducibility. The external quantum efficiency (EQE) was determined at zero bias by illuminating the device with monochromatic light supplied by a Xenon lamp in combination with a monochromator (Spectra Pro 150, Acton Research Corporation). The number of photons incident on the sample was calculated for each wavelength by using a Si photodiode calibrated by the manufacturer (Hamamatsu).

Instrumentation: Cyclic voltammograms were collected using a Solartron 1285 potentiostat under the control of CorrWare II software. A standard three electrode cell based on a Pt wire working electrode, a silver wire pseudo reference electrode (calibrated vs. Fc/Fc⁺), and a Pt wire counter electrode was purged with nitrogen and maintained under a nitrogen atmosphere during all measurements. Acetonitrile was purchased anhydrous from Aldrich and tetrabutylammonium hexafluorophosphate (0.1 M) was used as the supporting electrolyte. Polymer films were drop cast onto a Pt wire working electrode from a chloroform, tetrahydrofuran, toluene, or chlorobenzene solution and dried under nitrogen prior to measurement.

UV-Visible absorption spectra were obtained using a Cary 5000 Conc UV-Visible spectrophotometer in transmission geometry. For thin film measurements polymers were spin coated from chlorobenzene or chloroform solutions onto cleaned glass slides. Polymer film thickness was measured by a Veeco Dektak profilometer.

Atomic force microscopy (AFM) was performed to study the surface morphology of the polymer:PCBM blends. Topographical and phase images were obtained concurrently using a Veeco Multimode V AFM in tapping mode using RTESP tips.

TABLE 1
Device parameters of PDPP2FT:PC₆₁BM BHJ devices described herein.

| 1:3 PDPP2FT:PC₆₁BM | V_{oc} | J_{sc} (mA cm⁻²) | FF | PCE (%) |
|---|---|---|---|---|
| No additive | 0.76 | 7.8 | 0.57 | 3.4 (3.6) |
| 1 vol % CN | 0.76 | 8.9 | 0.54 | 3.7 (3.8) |

TABLE 2
Device parameters of PDPP3F solar cells described herein.

| | V_{oc} | J_{sc} (mA cm⁻²) | FF | PCE (%) |
|---|---|---|---|---|
| 1:3 PDPP3F:PC₆₁BM | | | | |
| No additive | 0.73 | 1.2 | 0.45 | 0.41 (0.47) |
| 5 vol % CN | 0.74 | 6.8 | 0.58 | 3.0 (3.4) |
| 1:3 PDPP3F:PC₇₁BM | | | | |
| No additive | 0.73 | 0.93 | 0.53 | 0.36 (0.41) |
| 5 vol % CN | 0.73 | 9.1 | 0.58 | 3.8 (4.1) |

In summary, we have shown that furans can be advantageously used as an alternative to thiophenes and thiophene-based building units in the design and synthesis of low band gap conjugated polymers with efficient solar cell performance. The polymers examined (PDPP2FT and PDPP3F) exhibit near-identical optical and electronic properties, and demonstrate power conversion efficiencies approaching 5% in BHJ devices with PC₇₁BM. The insertion of furan within the conjugated backbone allowed for shorter solubilizing groups to be used, compared to those required to solubilize the all-thiophene polymer PDPP3T. In particular, polymer solubility was found to improve substantially when a combination of thiophene and furan heterocycles is incorporated. The ca. 4% efficiency achieved with the all-furan low band gap polymer PDPP3F clearly demonstrates the potential of furans as thiophene alternatives in the design of highly performing organic solar cell materials, paving the path for the design and production of organic electronic materials from sustainable synthetic resources.

### REFERENCES CITED

(1) Dennler, G.; Scharber, M. C.; Brabec, C. J. Adv. Mater. 2009, 21, 1323-1338.
(2) Arias, A. C.; MacKenzie, J. D.; McCulloch, I.; Rivnay, J.; Salleo, A. Chem. Rev. 2010, 110, 3-24.
(3) Chen, J. W.; Cao, Y. Acct. Chem. Res. 2009, 42, 1709-1718.
(4) Cheng, Y. J.; Yang, S. H.; Hsu, C. S. Chem. Rev. 2009, 109, 5868-5923.
(5) Roncali, J. Macromol. Rapid Comm. 2007, 28, 1761-1775.
(6) Heremans, P.; Cheyns, D.; Rand, B. P. Acct. Chem. Res. 2009, 42, 1740-1747.
(7) Vandewal, K.; Tvingstedt, K.; Gadisa, A.; Inganäs, O.; Manca, J. V. Nat. Mater. 2009, 8, 904-909.
(8) Scharber, M. C.; Wuhlbacher, D.; Koppe, M.; Denk, P.; Waldauf, C.; Heeger, A. J.; Brabec, C. L. Adv. Mater. 2006, 18, 789-794.
(9) Veldman, D.; Meskers, S. C. J.; Janssen, R. A. J. Adv. Funct. Mater. 2009, 19, 1939-1948.
(10) Nguyen, L. H.; Hoppe, H.; Erb, T.; Gunes, S.; Gobsch, G.; Sariciftci, N. S. Adv. Funct. Mater. 2007, 17, 1071-1078.
(11) Gadisa, A.; Oosterbaan, W. D.; Vandewal, K.; Bolsee, J. C.; Bertho, S.; D'Haen, J.; Lutsen, L.; Vanderzande, D.; Manca, J. V. Adv. Funct. Mater. 2009, 19, 3300-3306.
(12) Wu, P. T.; Ren, G.; Jenekhe, S. A. Macromolecules 2010, 43, 3306-3313.
(13) Zoombelt, A. P.; Leenen, M. A. M.; Fonrodona, M.; Nicolas, Y.; Wienk, M. M.; Janssen, R. A. J. Polymer 2009, 50, 4564-4570.
(14) Huo, L. J.; Hou, J. H.; Chen, H. Y.; Zhang, S. Q.; Jiang, Y.; Chen, T. L.; Yang, Y. Macromolecules 2009, 42, 6564-6571.
(15) Piliego, C.; Holcombe, T. W.; Douglas, J. D.; Woo, C. H.; Beaujuge, P. M.; Fréchet, J. M. J. J. Am. Chem. Soc. 2010, 132, 7595-7596.
(16) Chen, M. H.; Hou, J.; Hong, Z.; Yang, G.; Sista, S.; Chen, L. M.; Yang, Y. Adv. Mater. 2009, 21, 4238-4242.
(17) Hou, J.; Chen, H. Y.; Zhang, S.; Li, G.; Yang, Y. J. Am. Chem. Soc. 2008, 130, 16144-16145.
(18) Park, S. H.; Roy, A.; Beaupre, S.; Cho, S.; Coates, N.; Moon, J. S.; Moses, D.; Leclerc, M.; Lee, K.; Heeger, A. J. Nat. Photon. 2009, 3, 297-302.
(19) Peet, J.; Kim, J. Y.; Coates, N. E.; Ma, W. L.; Moses, D.; Heeger, A. J.; Bazan, G. C. Nat. Mater. 2007, 6, 497-500.
(20) Liang, Y.; Feng, D.; Wu, Y.; Tsai, S. T.; Li, G.; Ray, C.; Yu, L. J. Am. Chem. Soc. 2009, 131, 7792-7799.
(21) Qin, R. P.; Li, W. W.; Li, C. H.; Du, C.; Veit, C.; Schleiermacher, H. F.; Andersson, M.; Bo, Z. S.; Liu, Z. P.; Inganäs, O.; Wuerfel, U.; Zhang, F. L. J. Am. Chem. Soc. 2009, 131, 14612-14613.
(22) Zou, Y. P.; Najari, A.; Berrouard, P.; Beaupre, S.; Aich, B. R.; Tao, Y.; Leclerc, M. J. Am. Chem. Soc. 2010, 132, 5330-5331.
(23) Huo, L. J.; Hou, J. H.; Zhang, S. Q.; Chen, H. Y.; Yang, Y. Angew. Chem. Int. Ed. 2010, 49, 1500-1503.
(24) Bunz, U. H. F. Angew. Chem. Int. Ed. 2010, 49, 5037-5040.
(25) Umeyama, T.; Takamatsu, T.; Tezuka, N.; Matano, Y.; Araki, Y.; Wada, T.; Yoshikawa, O.; Sagawa, T.; Yoshikawa, S.; Imahori, H. J. Phys. Chem. C 2009, 113, 10798-10806.
(26) Yamamoto, T.; Zhou, Z. H.; Kanbara, T.; Shimura, M.; Kizu, K.; Maruyama, T.; Nakamura, Y.; Fukuda, T.; Lee, B. L.; Ooba, N.; Tomaru, S.; Kurihara, T.; Kaino, T.; Kubota, K.; Sasaki, S. J. Am. Chem. Soc. 1996, 118, 10389-10399.
(27) Li, R. Z.; Lv, X. J.; Shi, D.; Zhou, D. F.; Cheng, Y. M.; Zhang, G. L.; Wang, P. J. Phys. Chem. C 2009, 113, 7469-7479.
(28) Lin, J. T.; Chen, P. C.; Yen, Y. S.; Hsu, Y. C.; Chou, H. H.; Yeh, M. C. P. Org. Lett. 2009, 11, 97-100.
(29) Walker, B.; Tomayo, A. B.; Dang, X. D.; Zalar, P.; Seo, J. H.; Garcia, A.; Tantiwiwat, M.; Nguyen, T. Q. Adv. Funct. Mater. 2009, 19, 3063-3069.
(30) Chen, Z. F.; Wannere, C. S.; Corminboeuf, C.; Puchta, R.; Schleyer, P. V. Chem. Rev. 2005, 105, 3842-3888.
(31) Zou, Y. P.; Gendron, D.; Neagu-Plesu, R.; Leclerc, M. Macromolecules 2009, 42, 6361-6365.
(32) Zou, Y. P.; Gendron, D.; Badrou-Aich, R.; Najari, A.; Tao, Y.; Leclerc, M. Macromolecules 2009, 42, 2891-2894.
(33) Zou, Y.; Najari, A.; Berrouard, P.; Beaupre¦ü, S.; Re¦üda Ai¦êch, B.; Tao, Y.; Leclerc, M. J. Am. Chem. Soc. 2010, 132, 5330-5331.
(34) Bijleveld, J. C.; Zoombelt, A. P.; Mathijssen, S. G. J.; Wienk, M. M.; Turbiez, M.; de Leeuw, D. M.; Janssen, R. A. J. J. Am. Chem. Soc. 2009, 131, 16616-16617.
(35) Gidron, O.; Diskin-Posner, Y.; Bendikov, M. J. Am. Chem. Soc. 2010, 132, 2148-2149.
(36) Miyata, Y.; Nishinaga, T.; Komatsu, K. J. Org. Chem. 2005, 70, 1147-1153.
(37) Hucke, A.; Cava, M. P. J. Org. Chem. 1998, 63, 7413-7417.
(38) Scully, S. R.; McGehee, M. D. J. Appl. Phys. 2006, 100, 034907.
(39) Shaw, P. E.; Ruseckas, A.; Samuel, I. D. W. Adv. Mater. 2008, 20, 3516-3520.
(40) Markov, D. E.; Amsterdam, E.; Blom, P. W. M.; Sieval, A. B.; Hummelen, J. C. J. Phys. Chem. A 2005, 109, 5266-5274.

### Example 2

### Side-Chain Tunability of Furan-Containing Low Band-Gap Polymers Provides Control of Structural Order in Efficient Solar Cells

The solution-processability of conjugated polymers in organic media has classically been achieved by modulating the size and branching of alkyl substituents appended to the backbone. However, these substituents impact structural order and charge transport properties in thin-film devices. As a result, a tradeoff must typically be found between material solubility and insulating alkyl content. Previously, the incorporation of furans along the backbone was shown to significantly improve polymer solubility, allowing for the use of relatively short branched side-chains while maintaining high device efficiency. In this report, we demonstrate that furans in the polymer backbone enable the use of linear n-alkyl side-chains, which promote nanostructural order in alternating furan-thiophene PDPP2FT polymers. In particular, linear side-chains are shown to shorten π-π stacking distances between backbones and increase the correlation lengths of both π-π stacking and lamellar spacing. Bulk heterojunction solar cells fabricated from these n-alkyl-substituted PDPP2FT polymer donors and the electron acceptor PC₇₁BM show improved power conversion efficiencies reaching 6.5%.

Introduction

In the growing market for clean energy, organic photovoltaic (OPV) technology is a promising candidate for achieving low-cost, high-throughput energy generation. It has thus become the focus of significant research effort, much of which is directed toward developing low band-gap polymer donors for use in bulk-heterojunction (BHJ) devices with fullerene-based electron acceptors.¹⁻⁹ Properties that influence the performance of these polymer donors include light absorption,¹⁰⁻¹² electronic compatibility with the fullerene acceptor,¹³⁻¹⁷ charge transport characteristics,¹⁸⁻²¹ and thin-film morphology²²⁻²⁴ and nanostructural order.²⁵⁻²⁷ One of the main goals in OPV research is to better understand the structure-property relationships that govern material performance. For a polymer, the chemical structures of both its backbone and its solubilizing side-chains have been shown to affect its solution-processability, miscibility with the fullerene acceptor, and thin-film structural order.^{16,27-29} However, structural changes often have competing effects on these properties and, in turn, on device performance. In particular, while increasing alkyl side-chain size may improve processability, it is also expected to increase insulating content and decrease crystallinity. Overcoming performance limitations imposed by these competing effects requires a means of optimizing one property with minimal adverse effect on other properties.

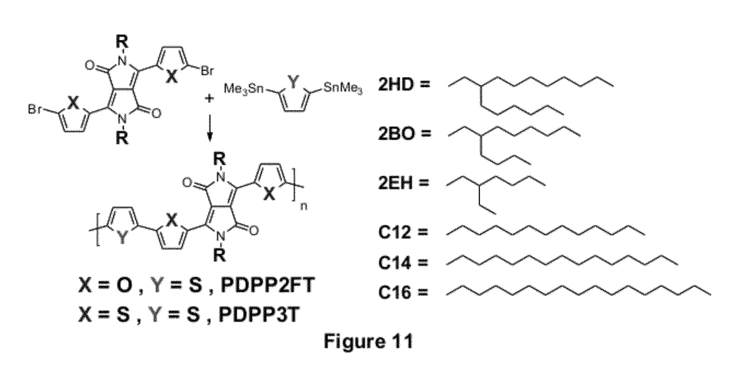

Recently, we demonstrated that furan (F) is a viable alternative to thiophene (T) in conjugated polymers for OPV applications.²⁹ This was shown in model low band-gap polymers based on the electron-deficient unit diketopyrrolopyrrole (DPP), which has raised considerable interest—primarily in combination with thiophene—for application in transistors and solar cells.^{15,30-37} DPP-based building blocks are particularly attractive for their scalable 3-4 step synthesis.^{15,29,33} With these model polymers, we showed that the incorporation of furan moieties into the polymer backbone imparts markedly improved solubility. As a result, the furan-containing polymer (PDPP2FT, see FIG. 11) is processable in common organic solvents (e.g., tetrahydrofuran, chlorobenzene, chloroform) with short 2-ethylhexyl (2EH) side-chains. In comparison, the analogous DPP-thiophene polymer (PDPP3T, see FIG. 11) requires much longer 2-hexyldecyl (2HD) side-chains, as previously reported by Janssen et al.³⁴ In BHJ devices with PC₇₁BM, both PDPP2FT-2EH and PDPP3T-2HD achieved comparable power conversion efficiencies (PCEs) of ca. 5%, showing that furan can be a viable alternative to thiophene.

In parallel, it is worth noting that the vast majority of polymer donors exhibiting high PCEs in BHJ devices have branching centers and substituents of various size and sterics.^{16,27,38-41} While these centers and substituents greatly improve polymer solution-processability in organic solvents, they may not be co-planar with the backbone. Increasing overall polymer planarity may ultimately promote self-assembly into extended crystalline domains with longer-range backbone alignment. In fact, OPV performance has often been shown to improve with increased molecular ordering in the active layer, as a result of improved continuity of charge transport pathways.^{42,43} The choice of alkyl side-chain structure has been shown to have a pronounced effect on this packing and, therefore, on overall device performance.²⁷

In this contribution, we demonstrate that linear n-alkyl side-chains can be used as alternatives to branched side-chains in order to promote nanostructural order in alternating furan-thiophene PDPP2FT polymers. Despite the absence of side-chain branching, the solution-processability of the polymers is retained due to the significant contribution of furans to overall polymer solubility. In contrast, PDPP3T polymers with the same linear side-chains are insufficiently soluble to be processed into functional devices. BHJ solar cells fabricated from n-alkyl-substituted PDPP2FT polymer donors and the electron-acceptor [6,6]-phenyl-C₇₁-butyric acid methyl ester (PC₇₁BM) exhibit PCEs reaching 6.5% (PDPP2FT-C₁₄). This high performance represents a substantial improvement over the PCE values of ca. 5% achieved with both the branched-alkyl-substituted derivative PDPP2FT-EH and the original thiophene-based analog PDPP3T-2HD. Importantly, linear side-chains are shown to improve nanostructural order by reducing the π-π (stacking distances between backbones and increasing the correlation lengths of both π-π stacking and lamellar spacing. The combination of design principles described in this report—the incorporation of furan to enable the use of linear side-chains—paves a path to reaching PCE values exceeding those presently obtained with other branched-alkyl-substituted thiophene-based polymer donors.^{15,34}

Results and Discussion

Synthesis and Optoelectronic Properties. To demonstrate the influence of linear side-chains on structural order in furan-containing polymer donors, the PDPP2FT derivatives PDPP2FT-C₁₂, PDPP2FT-C₁₄, and PDPP2FT-C₁₆ were synthesized with n-C₁₂, n-C₁₄, and n-C₁₆ side-chains, respectively (FIG. 11). Further shortening the side-chain to n-C₁₀ resulted in greatly reduced solubility, and the polymer could not be processed into solar cell devices. As control experiments, thiophene-based PDPP3T polymer analogs were synthesized with n-C₁₄ and n-C₁₆ side-chains, but these analogs also showed limited solubility and could not be solution processed. As demonstrated by the improved solubility of PDPP2FT, the incorporation of furan in the polymer backbone allows access to polymer designs that are not otherwise soluble or processable. In parallel, the branched-alkyl-substituted derivative PDPP2FT-2BO (FIG. 11) was prepared in order to further correlate the size of the branched substituents with structural order and solar cell device performance (see Supporting Information, SI). The synthesis of the branched-alkyl-substituted derivative PDPP2FT-2EH was reported earlier.²⁹ Synthetic details and molecular characterizations can be found in the SI.

Polymer thin-film absorption coefficients, optical band gaps, and photoelectron spectroscopy in air (PESA)-estimated highest occupied molecular orbital (HOMO) energy levels are summarized in Table 3. UV-Vis absorption spectra of the three n-alkyl-substituted PDPP2FT analogs are provided in the SI. The optical and electronic properties of all three derivatives are nearly identical and closely match those of the branched-alkyl-substituted analogs PDPP2FT-2EH²⁹ and PDDP3T-2HD³⁴.

TABLE 3
Optical and electrochemical properties of PDPP2FT polymers.

| | Extinction | Optical | HOMO |
|---|---|---|---|
| | coefficient^{a} | band gap^{b} | (PESA^{c}) |
| Derivative | [cm⁻¹] | [eV] | [eV] |
| C₁₂ | 1.1 × 10⁵ | 1.4 | −5.2 |
| C₁₄ | 7.7 × 10⁴ | 1.4 | −5.2 |
| C₁₆ | 6.5 × 10⁴ | 1.4 | −5.3 |

^{a}Measured at λₘₐₓ.
^{b}Based on absorption onsets.
^{c}Photoelectron spectroscopy in air (PESA) measurements.

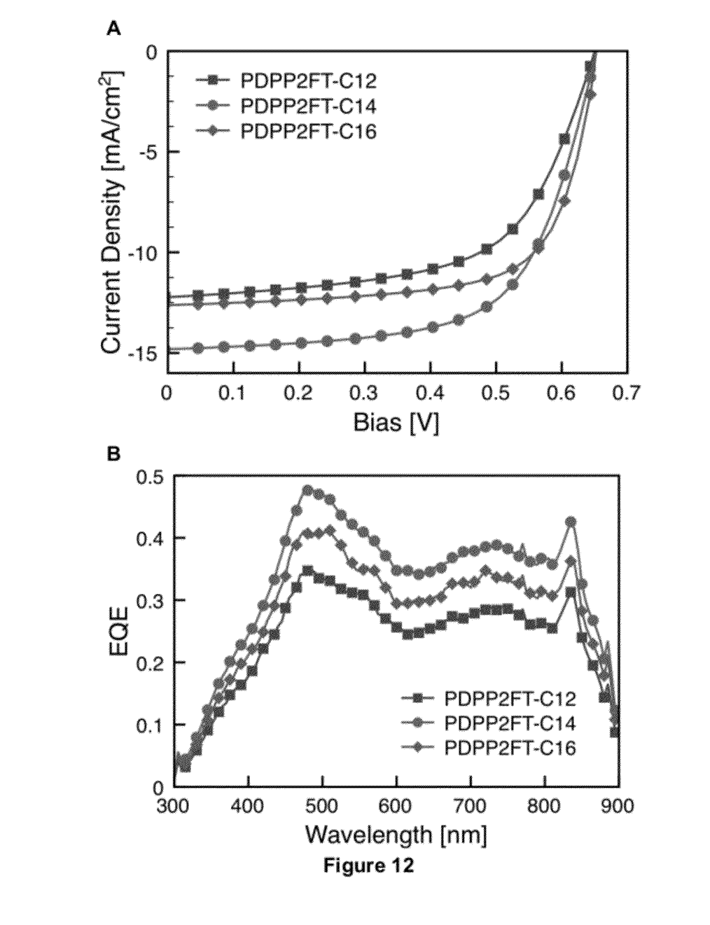

Device Fabrication and Testing. Thin-film BHJ solar cells were fabricated using the -alkyl-substituted derivatives PDPP2FT-C₁₂, -C₁₄, and -C₁₆ as electron donors and PC₇₁BM as the electron acceptor, with an optimized PDPP2FT:PC₇₁BM blend ratio of 1:3 by weight. The device architecture was ITO/PEDOT:PSS/polymer:PC₇₁BM/LiF/Al. Active layers were spin-coated from chloroform solutions, with a small amount of the processing additive 1-chloronaphthalene (CN)⁴⁴ used to improve device performance.⁴⁵⁻⁴⁷ Devices fabricated from the PDPP2FT-C₁₂, -C₁₄, and -C₁₆ derivatives achieved average PCEs of 4.8%, 6.2%, and 5.7%, respectively, with PDPP2FT-C₁₄ based devices reaching as high as 6.5% (Table 4). The performance of the n-C₁₄ and n-C₁₆ derivatives is substantially improved over that of the previously reported branched-alkyl-substituted analogs PDPP2FT-EH and PDPP3T-HD, both of which achieved a PCE of ca. 5%. This PCE improvement is mostly attributed to increases in photocurrent and fill factor (FF). As shown in the device current density-voltage (J-V) curves and external quantum efficiency (EQE) spectra (FIG. 12), PDPP2FT-C₁₄ based devices exhibit particularly high short-circuit current (J_{SC}) approaching 15 mA/cm² and a broad EQE spectrum approaching 50% efficiency at 500 nm. As all of the derivatives exhibit similar light absorption and electrical properties, it is likely that these performance improvements are due to changes in properties such as charge carrier mobility, film morphology, and nanostructural order.

TABLE 4
PV performance of PDPP2FT derivatives with PC₇₁BM.

| | | | | Avg. | Max. |
|---|---|---|---|---|---|
| | J_{SC} | V_{OC} | | PCE | PCE |
| Derivative | [mA/cm²] | [V] | FF | [%] | [%] |
| C₁₂ | −12.2 | 0.65 | 0.60 | 4.8 | 5.2 |
| C₁₄ | −14.8 | 0.65 | 0.64 | 6.2 | 6.5 |
| C₁₆ | −12.3 | 0.65 | 0.69 | 5.7 | 6.2 |

To determine the impact of side-chains on charge carrier mobility, hole mobility was examined using the space charge limited current (SCLC) model. In hole-only devices (see SI), neat films of PDPP2FT-C₁₂, -C₁₄, and -C₁₆ showed mobilities of 4×10⁻⁴, 7×10⁻⁴, and 2×10⁻³ cm⁻²/V-s, respectively. The high carrier mobility of these n-alkyl-substituted PDPP2FT derivatives is expected to contribute in part to the high photocurrents and fill factors observed in optimized BHJ devices (FIG. 12). For comparison, neat films of PDPP2FT-2EH showed a hole mobility of 2×10⁻³ cm²/V-s. As this is similar to the mobilities observed with PDPP2FT-C₁₄ and -C₁₆, it is likely that the performance improvement seen with the n-alkyl-substituted derivatives arises from other thin-film properties, such as blend morphology with PC₇₁BM and nanostructural order.

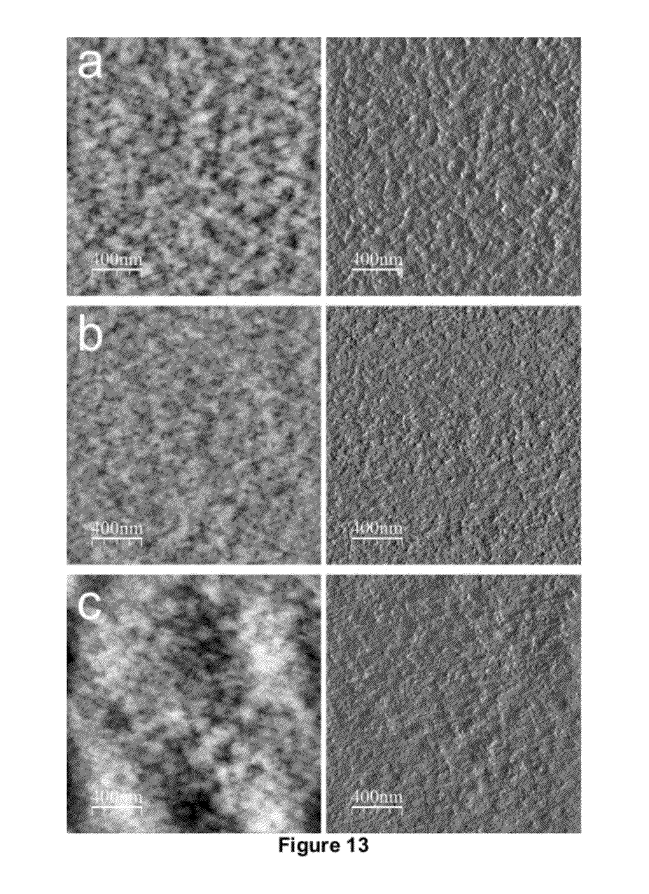

Thin-Film Morphology. Atomic force microscopy (AFM) was used to investigate the nanoscale morphology of the thin-film devices made from PDPP2FT-C₁₂, -C₁₄, and -C₁₆ blended with PC₇₁BM (FIG. 13). Notably, all films exhibit networks of morphological features on the order of ca. 20 nm in size. Excitons generated in donor phases of this size scale can diffuse to a donor/acceptor interface, assuming an exciton diffusion length of ca. 10 nm.^{48,49} As a polymer's solubilizing side-chains are expected to impact its solubility and miscibility with PC₇₁BM, they should also affect the film morphology that forms during the spin-coating process. As shown in FIG. 13, the thin-film devices made with PDPP2FT-C₁₄ are the smoothest, with a root mean square (RMS) roughness of 1.6 nm, as compared to 2.2 nm and 3.3 nm for those made with PDPP2FT-C₁₂ and PDPP2FT-C₁₆, respectively. The smoothness of the PDPP2FT-C₁₄ active layer suggests finer and more evenly distributed morphological features, which may reduce charge recombination. This observation is in agreement with solar cell efficiencies and other device parameters (Table 4). These results suggest that, with PDPP2FT, n-C₁₄ side-chains provide the most adequate combination of polymer solubility and miscibility with PC₇₁BM to achieve optimal film morphology.

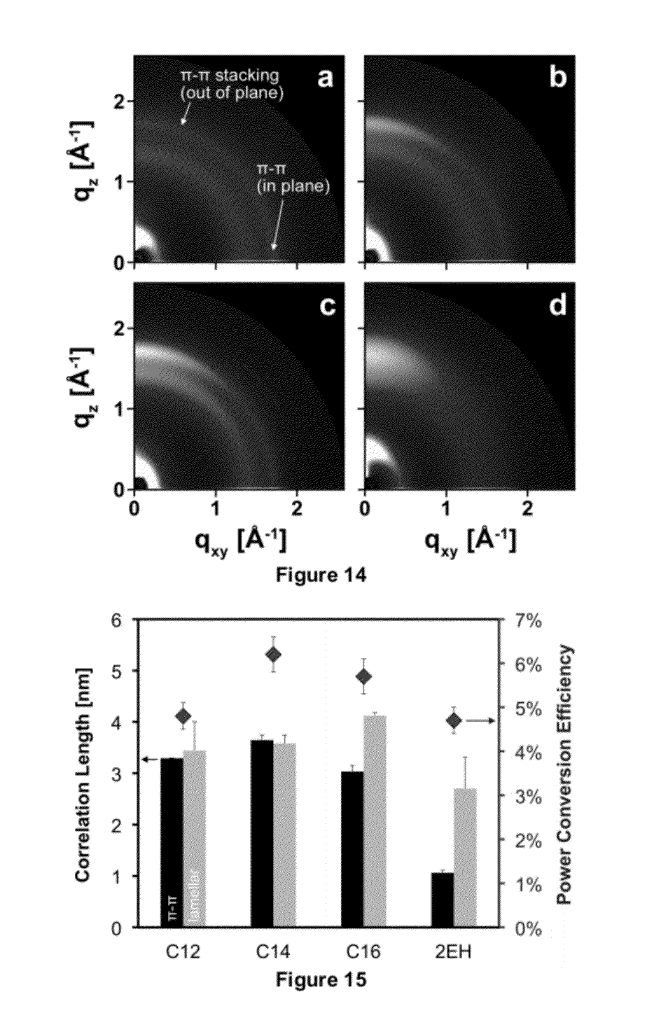

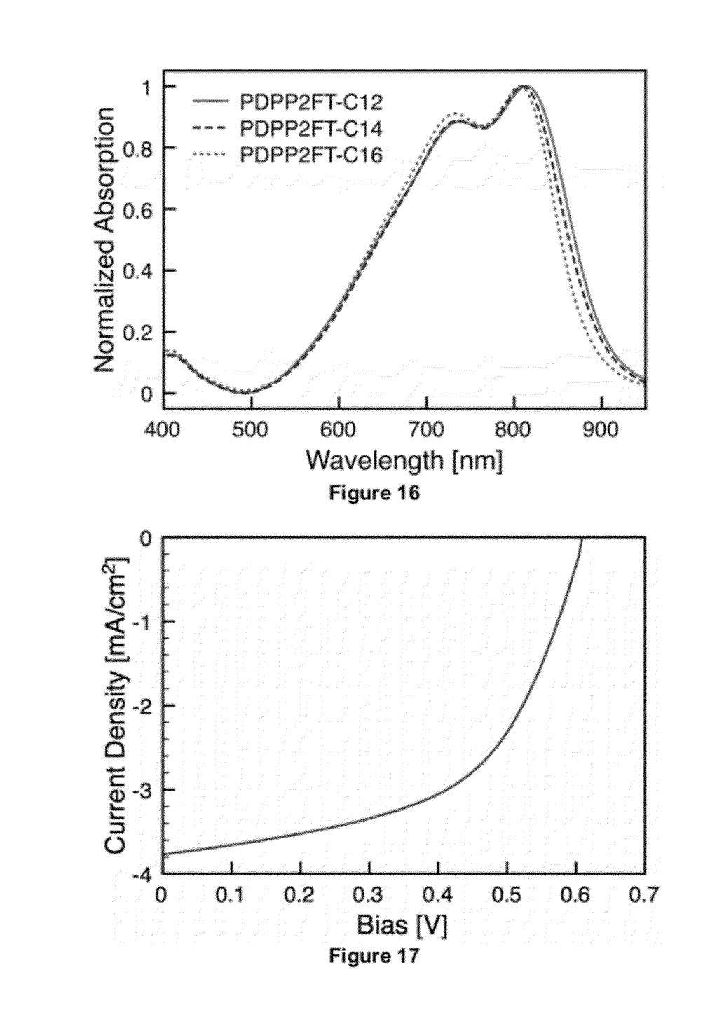

Thin-Film Nanostructural Order. To determine the influence of side-chain substitutions on nanostructural order within the active layer, grazing-incidence X-ray scattering (GIXS) was used to examine thin-films of PDPP2FT-C₁₂, -C₁₄, -C₁₆, and -2EH, both in neat polymer films (FIG. 14) and in optimized BHJ films with PC₇₁BM (see SI). GIXS data can be used to determine the nature and extent of the face-to-face packing of conjugated polymer backbones (π-π stacking). The scattering patterns of neat films of all four derivatives exhibit a π-π stacking peak, visible as a ring or partial arc at q ˜1.7 Å⁻¹. The stronger peak intensity near q_{xy}≈0 means that the π-π stacking is preferentially oriented out-of-plane, which has recently been correlated with high performance in OPV materials.^{28,50,51} In assessing the effect of these π-π interactions on solar cell performance, it is important to consider stacking distance. A shorter distance is thought to reduce the energetic barrier for charge hopping from one molecule to the next, promoting charge transport and improving device performance.^{52,53} It is expected that the solubilizing side-chains of a polymer will impact this π-π stacking distance. Compared to branched side-chains, which create steric hindrance when polymer chains are packed tightly, linear substituents are expected to be able to organize coplanar with the backbone, allowing for closer π-π stacking distances. In good agreement with this hypothesis, the π-π stacking distances for all three n-alkyl-substituted PDPP2FT derivatives are measured to be 3.6 Å, which is closer than the 3.7 Å stacking distances observed for PDPP2FT-2EH (see Table 5) and PDPP2FT-2BO (see SI), respectively. The shorter π-π spacings correlate well with the higher solar cell performance obtained with the n-alkyl-substituted derivatives. The consistent 3.6-Å π-π stacking distance for the three n-alkyl-substituted derivatives suggests that the n-alkyl side-chains are in fact lying relatively coplanar with the backbone, as any non-coplanarity should result in a chain-length-dependent impact on the stacking distance.

TABLE 5
GIXS peak parameters for PDPP2FT derivatives

| | |
|---|---|
| π-π stacking | Lamellar |
| peak | spacing peak |

| Derivative | d [Å] | L_{C} [nm] | d [Å] | L_{C} [nm] |
|---|---|---|---|---|
| C₁₂ | 3.6 | 3.3 | 21 | 3.4 |
| C₁₄ | 3.6 | 3.6 | 23 | 3.6 |
| C₁₆ | 3.6 | 3.0 | 25 | 4.1 |
| 2EH | 3.7 | 1.1 | 13 | 2.7 |

In addition to describing the molecular packing distances and orientation of crystallites in thin films, GIXS also provides information on the extent of nanostructural order. Specifically, GIXS can be used to determine the correlation length (L_{C}),^{25,54} which is a measure of the length scale over which one can expect a crystal lattice to be preserved. In polymer systems, order is expected to improve with the reduction of (i) the variability in chain position and rotation and (ii) the density of chain ends and lamellar folds.⁵² Correlation length can be determined using the Scherer equation,^{31,32} which takes scattering peak breadth as an input. As the order of crystalline domains increases, the corresponding scattering peaks become narrower. To determine the full width at half maximum (FWHM) peak breadths, peaks were fit to GIXS data averaged over quasi-polar angle (χ) for χ=20°±2° and χ=60°±2°. The resulting average correlation lengths are shown for π-π stacking and lamellar spacing peaks in Table 5 and FIG. 15. For ease of comparison, solar cell efficiencies (PCEs) are also reported in FIG. 15. Notably, the n-alkyl-substituted PDPP2FT derivatives pack with significantly longer π-π stacking correlation lengths (>3 nm) than do the branched-alkyl-substituted PDPP2FT-2EH analog (ca. 1 nm). Importantly, device performance is substantially improved in BHJs made with PDPP2FT-C₁₄, which also shows the largest π-π stacking correlation length at 3.6 nm. A similar trend is observed for lamellar spacing correlation lengths, which are greater for the n-alkyl-substituted derivatives (ca. 3-4 nm) than for the branched-alkyl-substituted derivatives (<3 nm). Although further studies would be required to determine the interdigitation and packing structure of the side-chains, it is important to note the apparent contribution of the linear chains to overall solid-state order and device performance. Increased order—particularly of π-π stacking—likely minimizes the number of defects that can trap charges and hinder their percolation across the active layer.^{43,55} As discussed earlier, the π-π stacking in these systems is preferentially oriented out-of-plane, which is also the desired hole transport direction. As a result, the effect of π-π stacking correlation length on solar cell device performance is expected to be particularly significant among factors contributing to improved performance.

Conclusions

In this report, we have demonstrated that long linear alkyl side-chains can be used as alternatives to branched side-chains on alternating furan-thiophene PDPP2FT polymers to promote nanostructural order in thin-film solar cells. Despite the absence of side-chain branching, the polymers' solution-processability is retained due to the significant contribution of the furan comonomer to overall polymer solubility. GIXS shows that linear side-chains in these systems (i) minimize the π-stacking distances between backbones and (ii) increase π-π stacking and lamellar spacing correlation lengths within polymer crystallites. Building from these design principles, we show that BHJ solar cells fabricated from n-alkyl-substituted substituted PDPP2FT polymer donors and the electron-acceptor PC₇₁BM exhibit PCEs reaching 6.5% (PDPP2FT-C₁₄). This high performance represents a substantial improvement over the PCE of ca. 5% achieved with the branched-alkyl-substituted derivative PDPP2FT-EH and the original thiophene-based analog PDPP3T-2HD.

This work demonstrates the great potential of furans in the design of polymer donors for efficient OPV applications. With their expanded structural design flexibility, alternating furan-thiophene low band-gap polymers pave a path to reaching PCE values exceeding those presently obtained with branched-alkyl-substituted thiophene-based polymer donors.

Supporting Information

Synthetic Details

Methods and Materials: All reagents from commercial sources were used without further purification, unless otherwise noted. Flash chromatography was performed using Silicycle SiliaFlash® P60 (particle size 40-63 μm, 230-400 mesh) silica gel. All compounds were characterized by ¹H NMR (400 MHz) and ¹³C NMR (100 MHz) on a Bruker AVQ-400 instrument or ¹³C NMR (150 MHz) on a Bruker AV-600 instrument. Notations for proton splitting patterns: s=singlet, d=doublet, t=triplet, q=quartet, dd=doublet of doublet, m=multiplet, and a=apparent. Matrix assisted laser desorption/ionization mass spectrometry (MALDI-TOF MS) was performed on a PerSeptive Biosystems Voyager-DE using 2,2′:5′,2″-terthiophene as the matrix. Samples were prepared by diluting the monomers in chloroform with the matrix. For the molecular weight determination of polymers, samples were dissolved in HPLC grade chloroform at a concentration of 1 mg/ml. The resulting solution was briefly heated and then allowed to return to room temperature prior to filtering through a 0.2 μm polyvinylidene fluoride (PVDF) filter. Size exclusion chromatography (SEC) was performed with HPLC grade chloroform at an elution rate of at 1.0 mL/min through three PLgel Mixed-C columns at room temperature. The particle size in the columns was 5 μm and the columns were maintained at room temperature. The SEC system consisted of a Waters 2695 Separation Module and a Waters 486 Tunable Absorption Detector. The apparent molecular weights and polydispersities (Mw/Mn) were determined with a calibration based on linear polystyrene standards using Millennium software from Waters.

The synthetic methods are adapted from those described in our early work on mixed furan-thiophene low band-gap conjugated polymers for solar cell applications: J. Am. Chem. Soc., 2010, 132 (44), pp 15547-15549.

Representative procedure for the synthesis of DPP2F monomer (4):

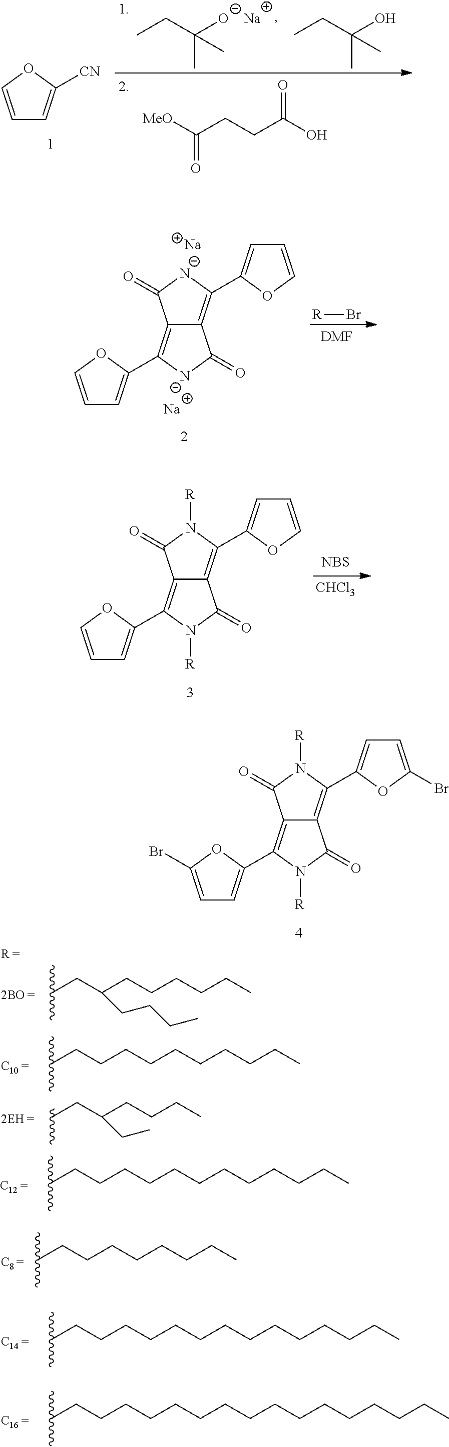

3,6-di(furan-2-yl)pyrrolo[3,4-c]pyrrole-1,4(2H,5H)-dione (2). A 500 mL three-neck round-bottom flask connected to a condenser was charged with a stir bar and tert-amyl alcohol (250 mL) under nitrogen atmosphere. Sodium metal pieces (2.47 g, 107 mmol) were added to the warmed solution of tert-amyl alcohol (60-70° C.) in small portions. After complete addition of the sodium, the temperature was progressively raised to 120° C. The mixture was stirred overnight at 120° C. Furan-2-carbonitrile (1) (10.0 g, 107 mmol) was subsequently added to the hot solution of sodium alkoxide. Dimethyl succinate (5.23 g, 35.8 mmol) was then added dropwise over a period of 20 min (the reaction mixture turned dark orange-red), and the resulting mixture was stirred for 1.5 h. The reaction mixture was then cooled to room temperature, and the precipitated sodium salt 2 was filtered over a Buchner funnel for collection and dried under vacuum (14.7 g, 87% yield). Compound 2 was used without further purification.

2,5-didodecyl-3,6-di(furan-2-yl)pyrrolo[3,4-c]pyrrole-1,4(2H,5H)-dione (3-C₁₂). Compound 2 (3.45 g, 11.05 mmol) and 50 mL of dry DMF were added to a 100 mL two-neck round-bottom flask, equipped with a condenser and stir-bar and placed under N₂ atmosphere. The mixture was heated to 120° C., stirred for 30 min, and 1-bromododecane (6.89 g, 27.63 mmol) was then added quickly (while at 120° C.). The reaction mixture was subsequently stirred at 140° C. for ca. 2 h, and cooled to room temperature. The organic phase was precipitated in water, the precipitate was filtered off, and dissolved in chloroform (CHCl₃). CHCl₃ was evaporated, and the resulting tacky solid (dark red) was purified by column chromatography using CHCl₃ as eluent. 1.9 g of 3-C₁₂ were isolated (28% yield). ¹H NMR (400 MHz, CDCl₃): δ (ppm)=8.30 (d, J=3.6 Hz, 2H), 7.63 (d, J=0.8 Hz, 2H), 6.69 (dd, J=1.6 Hz, 3.6 Hz, 2H), 4.10 (t, J=7.6 Hz, 4H), 1.72-1.65 (m, 4H), 1.40-1.24 (m, 36H), 0.87 (t, J=6.8 Hz, 6H). ¹³C NMR (100 MHz, CDCl₃): δ (ppm)=161.0, 145.3, 144.8, 133.8, 120.3, 113.6, 106.6, 42.6, 32.1, 30.4, 29.8, 29.7, 29.5, 29.4, 17.0, 22.8, 14.3. MALDI-TOF MS (m/z): calc'd for C₃₈H₅₆N₂O₄ [M⁺]=492.30; found 492.84.

Other alkyl-substituted derivatives (3) were obtained in comparable yields; their corresponding NMR and MALDI data are reported below:

2,5-di-(2-ethylhexyl)-3,6-di(furan-2-yl)pyrrolo[3,4-c]pyrrole-1,4(2H,5H)-dione (3-2EH). ¹H NMR (400 MHz, CDCl₃): δ (ppm)=8.33 (d, J=3.6 Hz, 2H), 7.61 (d, J=1.3 Hz, 2H), 6.69 (dd, J=1.7 Hz, 3.6 Hz, 2H), 4.04 (d, J=7.8 Hz, 4H), 1.80-1.68 (m, 2H), 1.39-1.26 (m, 16H), 0.95-0.85 (m, 12H). ¹³C NMR (100 MHz, CDCl₃): δ (ppm)=161.4, 145.0, 144.8, 134.1, 120.4, 113.6, 106.6, 46.3, 40.1, 30.7, 28.8, 24.0, 23.2, 14.2, 10.9. MALDI-TOF MS (m/z): calc'd for C₃₀H₄₀N₂O₄ [M⁺]=492.3; found 492.9.

2,5-di-(2-butyloctyl)-3,6-di(furan-2-yl)pyrrolo[3,4-c]pyrrole-1,4(2H,5H)-dione (3-2BO). ¹H NMR (400 MHz, CDCl₃): δ (ppm)=8.37 (d, J=3.6 Hz, 2H), 7.65 (d, J=1.5 Hz, 2H), 6.73 (dd, J=1.7 Hz, 3.7 Hz, 2H), 4.08 (d, J=7.5 Hz, 4H), 1.91-1.76 (m, 2H), 1.48-1.18 (m, 32H), 1.00-0.82 (m, 12H).

¹³C NMR (100 MHz, CDCl₃): δ (ppm)=161.3, 144.8, 144.7, 133.9, 120.2, 113.5, 106.5, 46.5, 38.5, 31.8, 31.5, 29.7, 26.5, 23.1, 22.7, 14.1. MALDI-TOF MS (m/z): calc'd for C₃₈H₅₆N₂O₄ [M⁺]=604.42; found 604.65.

2,5-dioctyl-3,6-di(furan-2-yl)pyrrolo[3,4-c]pyrrole-1,4(2H,5H)-dione (3-C₈). ¹H NMR (400 MHz, CDCl₃): δ (ppm)=8.30 (d, J=3.6 Hz, 2H), 7.63 (as, 2H), 6.69 (dd, J=1.2 Hz, 3.6 Hz, 2H), 4.04 (t, J=7.6 Hz, 4H), 1.75-1.67 (m, 4H), 1.20-1.45 (m, 20H), 0.86 (t, J=7.2 Hz, 6H). ¹³C NMR (100 MHz, CDCl₃): δ (ppm)=161.0, 145.3, 144.8, 133.8, 120.2, 113.6, 106.5, 42.5, 31.9, 30.4, 29.4, 29.3, 27.0, 22.8, 14.2. MALDI-TOF MS (m/z): calc'd for C₃₀H₄₀N₂O₄ [M⁺]=492.30; found 492.84.

2,5-didecyl-3,6-di(furan-2-yl)pyrrolo[3,4-c]pyrrole-1,4(2H,5H)-dione (3-C₁₀). ¹H NMR (400 MHz, CDCl₃): δ (ppm)=8.30 (d, J=3.6 Hz, 2H), 7.63 (d, J=0.8 Hz, 2H), 6.69 (dd, J=1.2 Hz, 3.8 Hz, 2H), 4.11 (t, J=7.2 Hz, 4H), 1.75-1.65 (m, 4H), 1.38-1.24 (m, 28H), 0.87 (t, J=6.8 Hz, 6H). ¹³C NMR (100 MHz, CDCl₃): δ (ppm)=161.0, 145.3, 144.8, 133.8, 120.3, 113.6, 106.6, 42.6, 32.0, 30.4, 29.7, 29.4, 27.0, 22.8, 14.3. MALDI-TOF MS (m/z): calc'd for C₃₄H₄₈N₂O₄ [M⁺]=548.36; found 548.77.

2,5-ditetradecyl-3,6-di(furan-2-yl)pyrrolo[3,4-c]pyrrole-1,4(2H,5H)-dione (3-C₁₄). ¹H NMR (400 MHz, CDCl₃): δ (ppm)=8.35 (d, J=3.2 Hz, 2H), 7.67 (d, J=1.3 Hz, 2H), 6.74 (dd, J=1.7 Hz, 3.6 Hz, 2H), 4.20-4.09 (m, 4H), 1.83-1.64 (m, 4H), 1.53-1.17 (m, 44H), 0.93 (t, J=6.7 Hz, 6H).

¹³C NMR (100 MHz, CDCl₃): δ (ppm)=160.9, 145.1, 144.7, 133.6, 120.1, 113.5, 106.4, 42.4, 29.7, 29.6, 29.4, 26.9, 22.7, 14.1. MALDI-TOF MS (m/z): calc'd for C₄₂H₆₄N₂O₄ [M⁺]=660.49; found 660.96.

2,5-dihexadecyl-3,6-di(furan-2-yl)pyrrolo[3,4-c]pyrrole-1,4(2H,5H)-dione (3-C₁₆). ¹H NMR (400 MHz, CDCl₃): δ (ppm)=8.35 (d, J=3.4 Hz, 2H), 7.67 (d, J=1.2 Hz, 2H), 6.74 (dd, J=1.7 Hz, 3.7 Hz, 2H), 4.20-4.09 (m, 4H), 1.83-1.65 (m, 4H), 1.50-1.22 (m, 52H), 0.94 (t, J=6.7 Hz, 6H). ¹³C NMR (100 MHz, CDCl₃): δ (ppm)=160.9, 145.1, 144.7, 133.7, 120.1, 113.5, 106.5, 42.4, 29.7, 29.6, 29.4, 26.9, 22.7, 14.1. MALDI-TOF MS (m/z): calc'd for C₄₆H₇₂N₂O₄ [M⁺]=716.55; found 717.43.

3,6-bis(5-bromofuran-2-yl)-2,5-didodecylpyrrolo[3,4-c]pyrrole-1,4(2H,5H)-dione (4-C₁₂). A 250 mL single-neck round-bottom flask charged with 3-C₁₂ (1.56 g, 2.58 mmol) and 100 mL of CHCl₃. The mixture was cooled to 0° C. and stirred while N-bromosuccinimide (NBS, 0.92 g, 5.16 mmol) was added in small portions. The mixture was maintained at 0° C. and stirred for 1 h following complete addition of NBS. Crushed ice was charged into the organic phase, the whole was transferred into a separatory funnel, and the organic phase was extracted with CHCl₃ and washed with water. The CHCl₃ was evaporated, and the resulting tacky solid (dark purple-red) was purified by column chromatography using CHCl₃ as eluent. 0.63 g of 4-C₁₂ were isolated (32% yield). ¹H NMR (400 MHz, CDCl₃): δ (ppm)=8.30 (d, J=3.7 Hz, 2H), 6.67 (d, J=3.7 Hz, 2H), 4.13-4.05 (m, 4H), 1.80-1.66 (m, 4H), 1.50-1.21 (m, 36H), 0.93 (t, J=6.7 Hz, 6H). ¹³C NMR (100 MHz, CDCl₃): δ (ppm)=160.5, 146.2, 132.5, 126.4, 122.1, 115.5, 106.3, 42.5, 30.2, 29.6, 29.4, 26.9, 22.7, 14.1. MALDI-TOF MS (m/z): calc'd for C₃₈H₅₄Br₂N₂O₄ [M⁺]=762.25; found 762.33.

Other alkyl-substituted derivatives (4) were obtained in comparable yields; their corresponding NMR and MALDI data are reported below:

3,6-bis(5-bromofuran-2-yl)-2,5-di-(2-ethylhexyl)-pyrrolo[3,4-c]pyrrole-1,4(2H,5H)-dione (4-2EH).¹H NMR (400 MHz, CDCl₃): δ (ppm)=8.33 (d, J=3.6 Hz, 2H), 7.61 (d, J=1.3 Hz, 2H), 6.69 (dd, J=1.7 Hz, 3.6 Hz, 2H), 4.04 (d, J=7.8 Hz, 4H), 1.80-1.68 (m, 2H), 1.39-1.26 (m, 16H), 0.95-0.85 (m, 12H). ¹³C NMR (100 MHz, CDCl₃): δ (ppm)=161.4, 145.0, 144.8, 134.1, 120.4, 113.6, 106.6, 46.3, 40.1, 30.7, 28.8, 24.0, 23.2, 14.2, 10.9. MALDI-TOF MS (m/z): calc'd for C₃₀H₄₀N₂O₄ [M⁺]=492.3; found 492.9.

3,6-bis(5-bromofuran-2-yl)-2,5-di-(2-butyloctyl)-pyrrolo[3,4-c]pyrrole-1,4(2H,5H)-dione (4-2BO). ¹H NMR (400 MHz, CDCl₃): δ (ppm)=8.34 (d, J=3.7 Hz, 2H), 6.67 (d, J=3.7 Hz, 2H), 4.04 (d, J=7.4 Hz, 4H), 1.89-1.75 (m, 2H), 1.50-1.18 (m, 32H), 0.93 (m, 12H). ¹³C NMR (100 MHz, CDCl₃): δ (ppm)=160.9, 146.2, 145.5, 132.8, 126.3, 120.2, 115.6, 106.3, 46.6, 38.8, 31.4, 29.8, 26.5, 23.2, 22.7, 14.1. MALDI-TOF MS (m/z): calc'd for C₃₈H₅₄Br₂N₂O₄ [M⁺]=762.25; found 762.89.

3,6-bis(5-bromofuran-2-yl)-2,5-dioctyl-pyrrolo[3,4-c]pyrrole-1,4(2H,5H)-dione (4-C₈). ¹H NMR (400 MHz, CDCl₃): δ (ppm)=8.25 (d, J=3.6 Hz, 2H), 6.63 (d, J=3.6 Hz, 2H), 4.05 (t, J=7.6 Hz, 4H), 1.69 (m, 4H), 1.40-1.27 (m, 20H), 0.87 (t, J=6.0 Hz, 6H). ¹³C NMR (100 MHz, CDCl₃): δ (ppm)=160.7, 146.3, 132.6, 126.6, 122.3, 115.7, 106.4, 42.6, 31.9, 30.3, 29.4, 27.0, 22.8, 14.3. MALDI-TOF MS (m/z): calc'd for C₃₀H₃₈Br₂N₂O₄ [M⁺]=650.12; found 650.87.

3,6-bis(5-bromofuran-2-yl)-2,5-didecyl-pyrrolo[3,4-c]pyrrole-1,4(2H,5H)-dione (4-C₁₀). ¹H NMR (400 MHz, CDCl₃): δ (ppm)=8.25 (d, J=3.6 Hz, 2H), 6.63 (d, J=3.6 Hz, 2H), 4.05 (t, J=7.6 Hz, 4H), 1.69 (m, 4H), 1.40-1.26 (m, 28H), 0.87 (t, J=6.4 Hz, 6H). ¹³C NMR (100 MHz, CDCl₃): δ (ppm)=160.5, 126.1, 132.5, 126.4, 122.1, 115.5, 106.2, 42.5, 31.9, 30.2, 29.6, 29.5, 29.3, 29.2, 26.8, 22.7, 14.1. MALDI-TOF MS (m/z): calc'd for C₃₄H₄₆Br₂N₂O₄ [M⁺]=706.18; found 706.37.

3,6-bis(5-bromofuran-2-yl)-2,5-ditetradecyl-pyrrolo[3,4-c]pyrrole-1,4(2H,5H)-dione (4-C₁₄). ¹H NMR (400 MHz, CDCl₃): δ (ppm)=8.30 (d, J=3.7 Hz, 2H), 6.68 (d, J=3.7 Hz, 2H), 4.20-4.00 (m, 4H), 1.80-1.67 (m, 4H), 1.51-1.20 (m, 44H), 0.94 (t, J=6.6 Hz, 6H). ¹³C NMR (100 MHz, CDCl₃): δ (ppm)=160.5, 146.2, 132.5, 126.4, 122.1, 115.5, 106.3, 42.5, 29.7, 29.6, 29.4, 26.9, 22.7, 14.1, 7.5. MALDI-TOF MS (m/z): calc'd for C₄₂H₆₂Br₂N₂O₄ [M⁺]=818.31; found 818.24.

3,6-bis(5-bromofuran-2-yl)-2,5-dihexadecyl-pyrrolo[3,4-c]pyrrole-1,4(2H,5H)-dione (4-C₁₆). ¹H NMR (400 MHz, CDCl₃): δ (ppm)=8.30 (d, J=3.7 Hz, 2H), 6.67 (d, J=3.7 Hz, 2H), 4.13-4.05 (m, 4H), 1.78-1.68 (m, 4H), 1.52-1.19 (m, 52H), 0.92 (t, J=6.6 Hz, 6H). ¹³C (150 MHz, CDCl₃, 50° C.): δ (ppm)=160.8, 146.5, 132.8, 126.5, 122.2, 115.7, 106.7, 42.7, 32.1, 30.4, 29.9, 29.8, 29.7, 29.5, 29.4, 27.1, 22.8, 14.2. MALDI-TOF MS (m/z): calc'd for C₄₆H₇₀Br₂N₂O₄ [M⁺]=874.37; found 874.02.

Representative procedure for the synthesis of PDPP2FT-R (6):

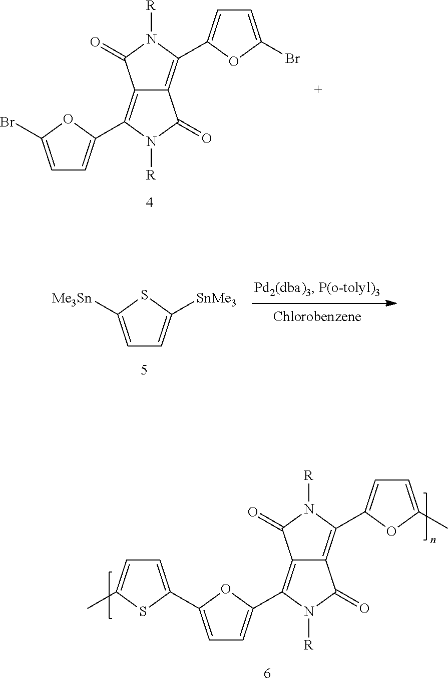

PDPP2FT-C₁₂ (6-C₁₂): 4 (160 mg, 0.210 mmol), 2,5-bis(trimethylstannyl)-thiophene (5) (85.97 mg, 0.210 mmol), Pd₂(dba)₃ (2 mol %) and P(o-tol)₃ (8 mol %) were charged within a 50 mL Schlenk tube, cycled with N₂ and subsequently dissolved in 9 mL of degassed chlorobenzene. The mixture was stirred for 24 h at 110° C. The reaction mixture was allowed to cool to 55° C., 15 mL of CHCl₃ was added, and the strongly complexing ligand N,N-diethylphenylazothioformamide (CAS#39484-81-6) was subsequently added (as a palladium scavenger). The resulting mixture was stirred for 1 h at 55° C., and precipitated into methanol (200 mL). The precipitate was filtered through a Soxhlet thimble and purified via Soxhlet extraction for 12 h with methanol and 1 h with hexanes, followed by collection in chloroform. The chloroform solution was concentrated by evaporation and precipitated into methanol (200 mL). The polymer 6 (PDPP2FT-C₁₂) was filtered off as a dark solid (41 mg). SEC analysis: see Table 6.

The SEC analyses for PDPP2FT-C₁₄, -C₁₆, -2EH and -2BO are also reported in Table 6. Polymers PDPP2FT-C₈ and -C₁₀ were not sufficiently soluble to be analyzed by SEC, and they were not sufficiently soluble to be tested in solar cell devices.

Representative procedure for the synthesis of DPP2T monomer (10):

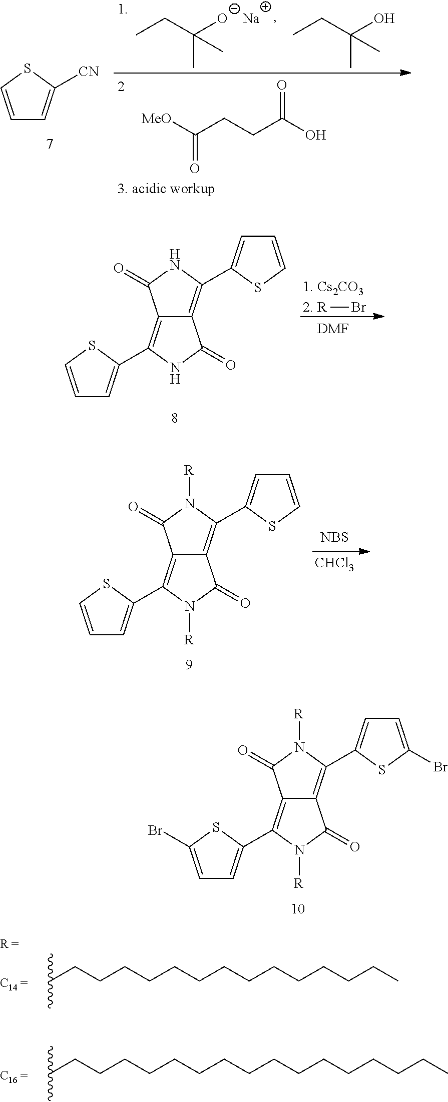

3,6-di(thiophene-2-yl)pyrrolo[3,4-c]pyrrole-1,4(2H,5H)-dione (8). A 500 mL three-neck flask connected to a condenser was charged with a stir bar and tert-amyl alcohol (250 mL). Sodium metal (2.56 g, 108 mmol) immersed in mineral oil was thoroughly washed with hexanes and cut into small pieces. The sodium metal pieces were slowly added to the reaction mixture over a 1.5 h period while the temperature was slowly increased to 120° C. over the same amount of time. After all the sodium metal pieces were dissolved, compound 7 (11.9 g, 108 mmol) was added to the reaction. As dimethyl succinate (5.29 g, 36.2 mmol) was added dropwise to the reaction mixture over 1 h, the solution turned dark red. The reaction contents were stirred at 120° C. for 2 h, and then precipitated into acidic MeOH (400 mL MeOH and 20 mL conc. HCl). Filtration of the suspension through a Buchner funnel yielded 8 as a dark red solid (9.10 g), which was used in subsequent reactions without further purification (83% yield).

2,5-ditetradecyl-3,6-di(thiophene-2-yl)pyrrolo[3,4-c]pyrrole-1,4(2H,5H)-dione (9-C₁₄). A 250 mL of round bottom flask was charged with 8 (2.00 g, 6.66 mmol), Cs₂CO₃ (6.51 g, 19.98 mmol) and dry DMF (55 mL). The reaction contents were stirred at 120° C. for 3 h before 1-bromotetradecane (4.62 g, 16.66 mmol) was added to the mixture. After the reaction mixture was heated at 130° C. for 20 h, it was precipitated into ice water. The crude materials were subsequently purified by flash chromatography (CHCl₃) to yield 2.07 g of purple solid (43%). ¹H NMR (400 MHz, CDCl₃): δ (ppm)=8.93 (d, J=3.6 Hz, 2H), 7.63 (d, J=4.8 Hz, 2H), 7.28 (dd, J=4.0 Hz, 4.8 Hz, 2H), 4.06 (t, J=8.0 Hz, 4H), 1.76-1.72 (m, 4H), 1.45-1.24 (m, 44H), 0.87 (t, J=6.8 Hz, 6H). ¹³C NMR (100 MHz, CDCl₃): δ (ppm)=161.5, 140.2, 135.4, 130.8, 129.9, 128.8, 107.8, 42.4, 32.1, 30.1, 29.8, 29.7, 29.5, 29.4, 27.0, 22.8, 14.3. MALDI-TOF MS (m/z): calc'd for C₄₂H₆₄N₂O₂S₂ [M⁺]=692.44; found 692.42.

2,5-dihexadecyl-3,6-di(thiophene-2-yl)pyrrolo[3,4-c]pyrrole-1,4(2H,5H)-dione (9-C₁₆). Followed the same synthetic procedure as for 9-C₁₄. Instead, used 8 (2.00 g, 6.66 mmol), Cs₂CO₃ (6.51 g, 19.98 mmol), 1-bromohexadecane (5.09 g, 16.66 mmol) and 55 mL of dry DMF. Worked up the reaction mixture by first precipitating it into ice and water, and filtered through a Buchner funnel. Dissolved the crude materials in CHCl₃, precipitated the solution into methanol to remove mono-alkylated products, and filtered to 2.99 g of purple solid (60%). ¹H NMR (400 MHz, CDCl₃): δ (ppm)=8.93 (d, J=3.6 Hz, 2H), 7.64 (d, J=5.2 Hz, 2H), 7.28 (dd, J=4.4 Hz, 4.8 Hz, 2H), 4.07 (t, J=8.0 Hz, 4H), 1.76-1.72 (m, 4H), 1.45-1.24 (m, 52H), 0.87 (t, J=6.8 Hz, 6H). ¹³C NMR (100 MHz, CDCl₃): δ (ppm)=161.5, 140.2, 135.4, 130.8, 129.9, 128.8, 107.8, 42.4, 32.1, 30.1, 29.8, 29.72, 29.68, 29.5, 29.4, 27.0, 22.8, 14.3. MALDI-TOF MS (m/z): calc'd for C₄₆H₇₂N₂O₂S₂ [M⁺]=748.50; found 747.92.

3,6-bis(5-bromothiophene-2-yl)-2,5-ditetradecyl-pyrrolo[3,4-c]pyrrole-1,4(2H,5H)-dione (10-C₁₄). A 100 mL single-neck round-bottom flask was charged with a stir bar, 9-C₁₄ (1.00 g, 1.44 mmol) and 20 mL of CHCl₃ under N₂. After the reaction mixture was stirred in an ice bath at 0° C. for 20 min, NBS (526 mg, 2.96 mmol) was added in small portions over 30 min. After stirring for another 2 h, the reaction mixture was diluted with 100 mL CHCl₃ and washed with water 3 times. The organic layer was dried over MgSO₄ and filtered. Since the product was not completely dissolved, hot CHCl₃ was used to wash and rinse down the purple solid. The resulting materials were recrystallized twice in CHCl₃ to yield the product as a purple solid (308 mg, 25%). Higher yields could have been obtained by further recrystallizing the mother liquor. ¹H NMR (400 MHz, CDCl₃): δ (ppm)=8.68 (d, J=4.0 Hz, 2H), 7.24 (d, J=4.0 Hz, 2H), 3.98 (t, J=7.6 Hz, 4H), 1.71-1.69 (m, 4H), 1.40-1.25 (m, 44H), 0.87 (t, J=6.4 Hz, 6H). ¹³C NMR (150 MHz, CDCl₃, 45° C.): δ (ppm)=161.3, 139.2, 135.4, 131.8, 131.4, 119.2, 108.2, 42.5, 32.1, 30.2, 29.9, 29.83, 29.81, 29.79, 29.72, 29.65, 29.5, 29.4, 27.0, 22.8, 14.2. MALDI-TOF MS (m/z): calc'd for C₄₂H₆₂Br₂N₂O₂S₂ [M⁺]=850.26; found 849.70.

3,6-bis(5-bromothiophene-2-yl)-2,5-dihexadecyl-pyrrolo[3,4-c]pyrrole-1,4(2H,5H)-dione (10-C₁₆). Followed the same synthetic procedure as for 10-C₁₄. Instead, used 9-C₁₆ (1.50 g, 2.00 mmol), NBS (730 mg, 4.10 mmol) and 80 mL of CHCl₃ in a 250-mL RBF. The reaction mixture appeared as a purple suspension. After stirring at room temperature after 2 d under N₂, the suspension was precipitated into 50 mL of MeOH and filtered. The resulting materials were recrystallized five times in CHCl₃ to yield the product as a purple solid (534 mg, 30%). Higher yields could have been obtained by further recrystallizing the mother liquor. ¹H NMR (400 MHz, CDCl₃): δ (ppm)=8.68 (d, J=4.0 Hz, 2H), 7.23 (d, J=4.0 Hz, 2H), 3.98 (t, J=7.6 Hz, 4H), 1.73-1.69 (m, 4H), 1.40-1.25 (m, 52H), 0.88 (t, J=6.4 Hz, 6H). ¹³C NMR (150 MHz, CDCl₃, 45° C.): δ (ppm)=161.3, 139.2, 135.4, 131.8, 131.4, 119.2, 108.2, 42.5, 32.1, 30.2, 29.86, 29.83, 29.82, 29.80, 29.72, 29.65, 29.5, 29.4, 27.0, 22.8, 14.2. MALDI-TOF MS (m/z): calc'd for C₄₆H₇₀Br₂N₂O₂S₂ [M⁺]=904.32; found 904.81.

Representative procedure for the synthesis of PDPP3T-R (11):

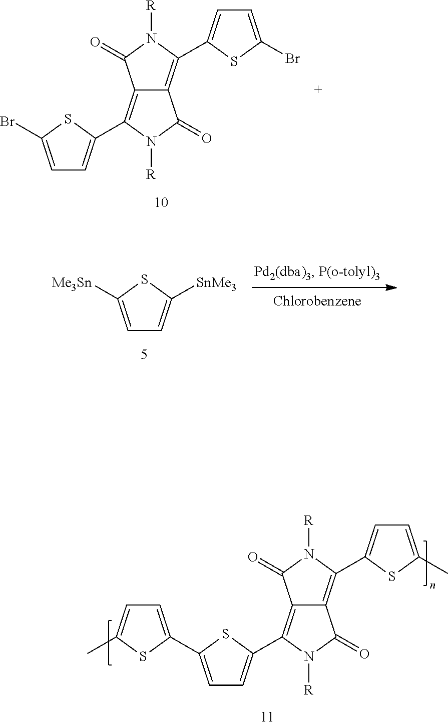

PDPP3T-C₁₄ (11-C₁₄). The same polymerization protocol as that described for PDPP2FT-C₁₂ (6-C₁₂) was followed. Instead, used 10-C₁₄ (150 mg, 176 μmol), 5 (72.2 mg, 176 μmol), Pd₂(dba)₃ (3.23 mg, 3.53 μmol) and P(o-tol)₃ (4.29 mg, 14.1 μmol) in 5.3 mL of degassed chlorobenzene. After 24 h, the reaction was cooled to room temperature and aliquots were taken for SEC analysis (˜1 mL was extracted from the reaction mixture and precipitated into ˜3 mL of methanol). Results of SEC analysis are shown in Table 6.

PDPP3T-C₁₆ (11-C₁₆). The same polymerization protocol as that described for PDPP2FT-C₁₂ (6-C₁₂) was followed. Instead, used 10-C₁₆ (160 mg, 176 μmol, 5 (72.2 mg, 176 μmol), Pd₂(dba)₃ (3.23 mg, 3.53 μmol) and P(o-tol)₃ (4.29 mg, 14.1 μmol) in 5.5 mL of degassed chlorobenzene. The reaction mixture formed a gel-like materials after 15 min of heating at 110° C., and it was continued to be heated at 110° C. for 24 h. The reaction was then cooled to room temperature and aliquots were taken for SEC analysis (˜1 mL was extracted from the reaction mixture and precipitated into ˜3 mL of methanol). Results of SEC analysis is shown in Table 6.

TABLE 6
SEC analysis of PDPP2FT and PDPP3T derivatives.

| Polymers | Mₙ (kDa) | M_{w} (kDa) | PDI |
|---|---|---|---|
| PDPP2FT-2EH | 56 | 88 | 1.57 |
| PDPP2FT-2BO | 54 | 85 | 1.56 |
| PDPP2FT-C₁₂ | 46 | 78 | 1.70 |
| PDPP2FT-C₁₄ | 58 | 92 | 1.59 |
| PDPP2FT-C₁₆ | 55 | 87 | 1.60 |
| PDPP3T-C₁₄ | <1 | <1 | — |
| PDPP3T-C₁₆ | 0.95 | 1.9 | 1.98 |

Device Fabrication and Testing

Substrate Preparation

All devices were fabricated on ITO-coated glass substrates (pre-patterned, R=20Ω⁻¹, Thin Film Devices, Inc.). To clean and prepare these substrates for device fabrication, the following procedure was followed:
Sonicate for 20 minutes in 2% Helmanex soap water, then rinse thoroughly with deionized (DI) water
Sonicate for 20 minutes in DI water
Sonicate for 20 minutes in acetone
Sonicate for 20 minutes in isopropyl alcohol, then dry under a stream of air
UV-ozone clean for 5 minutes
Spin-coat a thin layer (30-40 nm) of PEDOT:PSS (Clevios PVP) at 4000 RPM for 40 s, then dry in air for 10 minutes at 140° C.
Transfer to glovebox under N₂

Solar Cell Device Preparation

Using substrates prepared as described above, the following procedure was followed to prepare solar cell devices:
Prepare blend solution in CHCl₃ with a polymer:PC₇₁BM ratio of 1:3 by mass and a total solids concentration of 10.67 mg/mL for PDPP2FT-C₁₂ and -C₁₄ and 16 mg/mL for PDPP2FT-C₁₆ and -2BO
Add 5% by volume of high-boiling additive 1-chloronapthalene (CN)
Spin-coat onto substrate at 2000 RPM for 40 s, followed by 4000 RPM for 5 s
Dry under low vacuum for 20 minutes
Thermally evaporate cathodes (1 nm LiF, 100 nm Al) under vacuum (˜10⁻⁷ torr) through a shadow mask defining an active area of ˜0.03 cm⁻²

SCLC Device Preparation

Using substrates prepared as described above, the following procedure was followed to prepare SCLC devices:
Prepare polymer solution in CHCl₃ at a concentration of 8 mg/mL for PDPP2FT-C₁₋₁₂ and -C₁₄ and 10 mg/mL for PDPP2FT-C₁₆ and -2BO
Add 5% by volume of high-boiling additive CN
Spin-coat onto substrate at either 1000 or 2000 RPM for 40 s (to vary thickness), followed by 4000 RPM for 5 s
Dry under low vacuum for 20 minutes
Thermally evaporate cathodes (50 nm Au) under vacuum (˜10⁻⁷ torr) through a shadow mask defining an active area of ˜0.03 cm⁻²

Material Characterization and Device Testing

UV-Vis Absorption

Thin-film UV-Vis absorption spectra (Figure S-1) were measured with an Varian Cary 5000 spectrophotometer. Thin-films were spin-coated from CHCl₃ onto untreated quartz slides.

Device Testing

Current-voltage (J-V) curves were measured using a Keithley 2400 source-measure unit. Solar cell devices were tested under AM 1.5 G solar illumination at 100 mW cm⁻² using a Thermal-Oriel 150 @ solar simulator. For SCLC devices of each material, mobility values for two different film thicknesses were averaged to give the values provided.

Devices fabricated from PDPP2FT-2BO had a relatively low average PCE of 1.3%, with a V_{OC} of 0.61 V, a J_{SC} of −3.8 mA/cm², and a FF of 0.55 (FIG. 17).

Surface Topography

Height profiles of the active layers of devices were imaged using a Veeco Multimode V Atomic Force Microscope (AFM) operated in tapping mode.

X-Ray Scattering

Grazing-incidence x-ray scattering (GIXS) experiments were conducted at the Stanford Synchotron Radiation Lightsource on beamline 11-3. Substituting Si for ITO on glass, samples were prepared following the aforementioned procedure for SCLC devices (for neat polymer films) or for solar cell devices (for blend films). Samples were irradiated at a fixed incident angle of approximately 0.1° and their GIXS patterns were recorded with a 2-D image detector (MAR345 image plate detector). GIXS patterns were recorded with an X-ray energy of 12.71 keV (λ=0.975 Å). To maximize the intensity from the sample, the incident angle (˜0.08°-0.12°) was carefully chosen such that the X-ray beam penetrated the sample completely but did not interact significantly with the silicon substrate. Typical exposure times were 30-600 s.

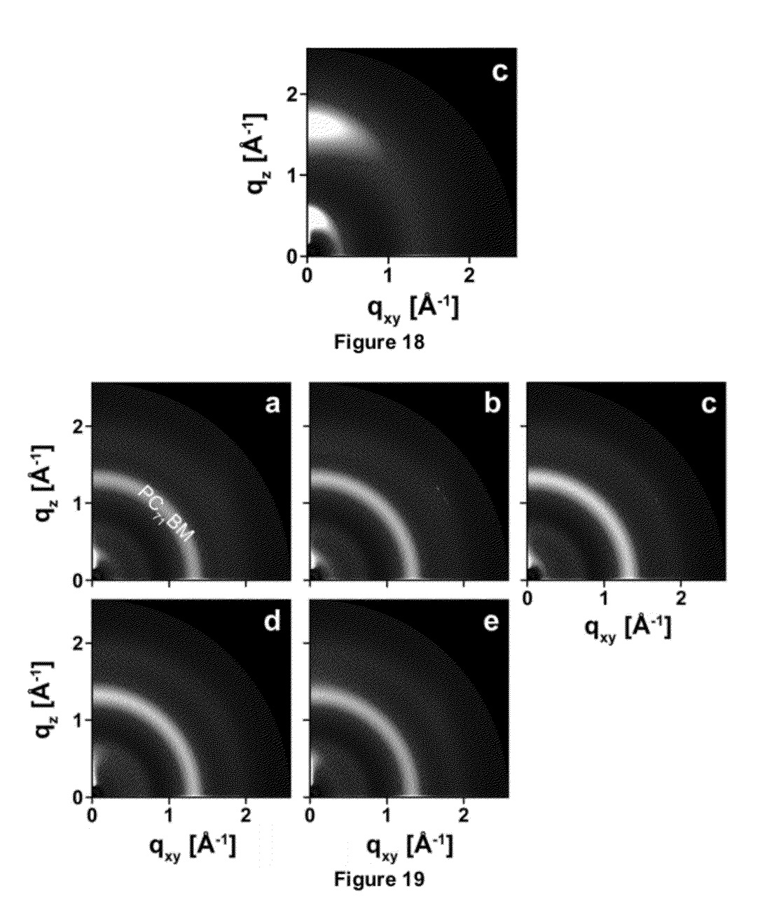

Analysis of GIXS scattering profiles of PDPP2FT-2BO (FIG. 18) indicate a π-π stacking distance of 3.9 Å, a π-π stacking correlation length of 1.2 nm, a lamellar spacing distance of 14 Å, and a lamellar spacing correlation length of 2.5 nm. The large π-π stacking distance and short correlation lengths agree with the poor performance of devices fabricated from PDPP2FT-2BO. GIXS scattering profiles of blend (BHJ) films (FIG. 19) exhibit peaks similar peaks to those of the neat films, but the intensity of the PC₇₁BM ring adds difficulty to a correlation length analysis.

### REFERENCES CITED

(1) Thompson, B. C.; Fréchet, J. M. J. Angew. Chem. Int. Ed. 2008, 47, 58.
(2) Dennler, G.; Scharber, M. C.; Brabec, C. J. Adv. Mater. 2009, 21, 1323.
(3) Scharber, M. C.; Mühlbacher, D.; Koppe, M.; Denk, P.; Waldauf, C.; Heeger, A. J.; Brabec, C. J. Adv. Mater. 2006, 18, 789.
(4) Chen, J.; Cao, Y. Acc. Chem. Res. 2009, 42, 1709.
(5) Gunes, S.; Neugebauer, H.; Sariciftci, N. S. Chem. Rev. 2007, 107, 1324.
(6) Li, C.; Liu, M.; Pschirer, N. G.; Baumgarten, M.; Müllen, K. Chem. Rev. 2010, ASAP.
(7) Bundgaard, E.; Krebs, F. C. Sol. Energ. Mat. Sol. Cells 2007, 91, 954.
(8) Boudreault, P.-L. T.; Najari, A.; Leclerc, M. Chem. Mater. 2011, 23, 456.
(9) Li, Y.; Sonar, P.; Singh, S. P.; Soh, M. S.; van Meurs, M.; Tan, J. J. Am. Chem. Soc. 2011, 133, 2198.
(10) Li, Y.; Zou, Y. Adv. Mater. 2008, 20, 2952.
(11) Hou, J.; Tan, Z. a.; Yan, Y.; He, Y.; Yang, C.; Li, Y. J. Am. Chem. Soc. 2006, 128, 4911.
(12) Roncali, J. Macomol. Rapid Comm. 2007, 28, 1761.
(13) Varotto, A.; Treat, N. D.; Jo, J.; Shuttle, C. G.; Batara, N. A.; Brunetti, F. G.; Seo, J. H.; Chabinyc, M. L.; Hawker, C. J.; Heeger, A. J.; Wudl, F. Angew. Chem. Int. Ed. 2011, 50, 5166.
(14) Veldman, D.; Meskers, S. C. J.; Janssen, R. A. J. Adv. Funct. Mater. 2009, 19, 1939.
(15) Wienk, M. M.; Turbiez, M.; Gilot, J.; Janssen, R. A. J. Adv. Mater. 2008, 20, 2556.
(16) Chen, H.-Y.; Hou, J.; Zhang, S.; Liang, Y.; Yang, G.; Yang, Y.; Yu, L.; Wu, Y.; Li, G. Nat. Photon. 2009, 3, 649.
(17) Zhou, H.; Yang, L.; Price, S. C.; Knight, K. J.; You, W. Angew. Chem. Int. Ed. 2010, 49, 7992.
(18) Blom, P. W. M.; Mihailetchi, V. D.; Koster, L. J. A.; Markov, D. E. Adv. Mater. 2007, 19, 1551.
(19) Parmer, J. E.; Mayer, A. C.; Hardin, B. E.; Scully, S. R.; McGehee, M. D.; Heeney, M.; McCulloch, I. Appl. Phys. Lett. 2008, 92, 113309.
(20) Coropceanu, V.; Cornil, J.; da Silva Filho, D. A.; Olivier, Y.; Silbey, R.; Brédas, J.-L. Chem. Rev. 2007, 107, 926.
(21) Johns, J. E.; Muller, E. A.; Frechet, J. M. J.; Harris, C. B. J. Am. Chem. Soc. 2010, 132, 15720.
(22) Peet, J.; Heeger, A. J.; Bazan, G. C. Acc. Chem. Res. 2009, 42, 1700.
(23) Di Nuzzo, D.; Aguirre, A.; Shahid, M.; Gevaerts, V. S.; Meskers, S. C. J.; Janssen, R. A. J. Adv. Mater. 2010, 22, 4321.
(24) Perez, M. D.; Borek, C.; Forrest, S. R.; Thompson, M. E. J. Am. Chem. Soc. 2009, 131, 9281.
(25) Rogers, J. T.; Schmidt, K.; Toney, M. F.; Kramer, E. J.; Bazan, G. C. Adv. Mater. 2011, 23, 2284.
(26) Salleo, A.; Kline, R. J.; DeLongchamp, D. M.; Chabinyc, M. L. Adv. Mater. 2010, 22, 3812.
(27) Piliego, C.; Holcombe, T. W.; Douglas, J. D.; Woo, C. H.; Beaujuge, P. M.; Fréchet, J. M. J. J. Am. Chem. Soc. 2010, 132, 7595.
(28) Beaujuge, P. M.; Pisula, W.; Tsao, H. N.; Ellinger, S.; Müllen, K.; Reynolds, J. R. J. Am. Chem. Soc. 2009, 131, 7514.
(29) Woo, C. H.; Beaujuge, P. M.; Holcombe, T. W.; Lee, O. P.; Fréchet, J. M. J. J. Am. Chem. Soc. 2010, 132, 15547.
(30) Khlyabich, P. P.; Burkhart, B.; Ng, C. F.; Thompson, B. C. Macromolecules 2011, 44, 5079.
(31) Mei, J.; Graham, K. R.; Stalder, R.; Tiwari, S. P.; Cheun, H.; Shim, J.; Yoshio, M.; Nuckolls, C.; Kippelen, B.; Castellano, R. K.; Reynolds, J. R. Chem. Mater. 2011, 23, 2285.
(32) Bronstein, H.; Chen, Z.; Ashraf, R. S.; Zhang, W.; Du, J.; Durrant, J. R.; Shakya Tuladhar, P.; Song, K.; Watkins, S. E.; Geerts, Y.; Wienk, M. M.; Janssen, R. A. J.; Anthopoulos, T.; Sirringhaus, H.; Heeney, M.; McCulloch, I. J. Am. Chem. Soc. 2011, 133, 3272.
(33) Walker, B.; Tamayo, A., B.; Dang, X.-D.; Zalar, P.; Seo, J. H.; Garcia, A.; Tantiwiwat, M.; Nguyen, T.-Q. Adv. Funct. Mater. 2009, 19, 3063.
(34) Bijleveld, J. C.; Zoombelt, A. P.; Mathijssen, S. G. J.; Wienk, M. M.; Turbiez, M.; de Leeuw, D. M.; Janssen, R. A. J. J. Am. Chem. Soc. 2009, 131, 16616.
(35) Loser, S.; Bruns, C. J.; Miyauchi, H.; Ortiz, R. P.; Facchetti, A.; Stupp, S. I.; Marks, T. J. J. Am. Chem. Soc. 2011, 133, 8142.
(36) Sonar, P.; Singh, S. P.; Li, Y.; Soh, M. S.; Dodabalapur, A. Adv. Mater. 2010, 22, 5409.
(37) Tamayo, A. B.; Dang, X.-D.; Walker, B.; Seo, J.; Kent, T.; Nguyen, T.-Q. Appl. Phys. Lett. 2009, 94, 103301.
(38) Hou, J.; Chen, H.-Y.; Zhang, S.; Li, G.; Yang, Y. J. Am. Chem. Soc. 2008, 130, 16144.
(39) Park, S. H.; Roy, A.; Beaupre, S.; Cho, S.; Coates, N.; Moon, J. S.; Moses, D.; Leclerc, M.; Lee, K.; Heeger, A. J. Nat. Photon. 2009, 3, 297.
(40) Scharber, M. C.; Koppe, M.; Gao, J.; Cordella, F.; Loi, M. A.; Denk, P.; Morana, M.; Egelhaaf, H.-J.; Forberich, K.; Dennler, G.; Gaudiana, R.; Waller, D.; Zhu, Z.; Shi, X.; Brabec, C. J. Adv. Mater. 2010, 22, 367.
(41) Hsiang-Yu, C.; Jianhui, H.; Amy, E. H.; Hoichang, Y.; Houk, K. N.; Yang, Y. Adv. Mater. 2010, 22, 371.
(42) McCulloch, I.; Heeney, M.; Bailey, C.; Genevicius, K.; MacDonald, I.; Shkunov, M.; Sparrowe, D.; Tierney, S.; Wagner, R.; Zhang, W.; Chabinyc, M. L.; Kline, R. J.; McGehee, M. D.; Toney, M. F. Nat. Mater. 2006, 5, 328.
(43) Wang, C.; Jimison, L. H.; Goris, L.; McCulloch, I.; Heeney, M.; Ziegler, A.; Salleo, A. Adv. Mater. 2010, 22, 697.
(44) Hoven, C. V.; Dang, X.-D.; Coffin, R. C.; Peet, J.; Nguyen, T.-Q.; Bazan, G. C. Adv. Mater. 2010, 22, E63.
(45) Peet, J.; Kim, J. Y.; Coates, N. E.; Ma, W. L.; Moses, D.; Heeger, A. J.; Bazan, G. C. Nat. Mater. 2007, 6, 497.
(46) Lee, J. K.; Ma, W. L.; Brabec, C. J.; Yuen, J.; Moon, J. S.; Kim, J. Y.; Lee, K.; Bazan, G. C.; Heeger, A. J. J. Am. Chem. Soc. 2008, 130, 3619.
(47) Peet, J.; Heeger, A. J.; Bazan, G. C. Acc. Chem. Res. 2009, 42, 1700.
(48) Yu, G.; Heeger, A. J. J. Appl. Phys. 1995, 78, 4510.
(49) Halls, J. J. M.; Walsh, C. A.; Greenham, N. C.; Marseglia, E. A.; Friend, R. H.; Moratti, S. C.; Holmes, A. B. Nature 1995, 376, 498.
(50) Guo, J.; Liang, Y.; Szarko, J.; Lee, B.; Son, H. J.; Rolczynski, B. S.; Yu, L.; Chen, L. X. J. Phys. Chem. B 2009, 114, 742.
(51) Beiley, Z. M.; Hoke, E. T.; Noriega, R.; Dacuña, J.; Burkhard, G. F.; Bartelt, J. A.; Salleo, A.; Toney, M. F.; McGehee, M. D. Adv. Energ. Mater. 2011, n/a.
(52) Street, R. A.; Northrup, J. E.; Salleo, A. Phys. Rev. B 2005, 71, 165202.
(53) Kim, Y.; Cook, S.; Tuladhar, S. M.; Choulis, S. A.; Nelson, J.; Durrant, J. R.; Bradley, D. D. C.; Giles, M.; McCulloch, I.; Ha, C.-S.; Ree, M. Nat Mater 2006, 5, 197.
(54) Warren, B. E. X-Ray Diffraction; Addison-Wesley: Reading, Mass., 1969.
(55) Rivnay, J.; Noriega, R.; Northrup, J. E.; Kline, R. J.; Toney, M. F.; Salleo, A. Phys. Rev. B 2011, 83, 121306.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

What is claimed is:

1. A polymer comprising the following chemical structure: 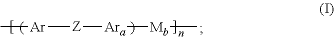
wherein Z is: 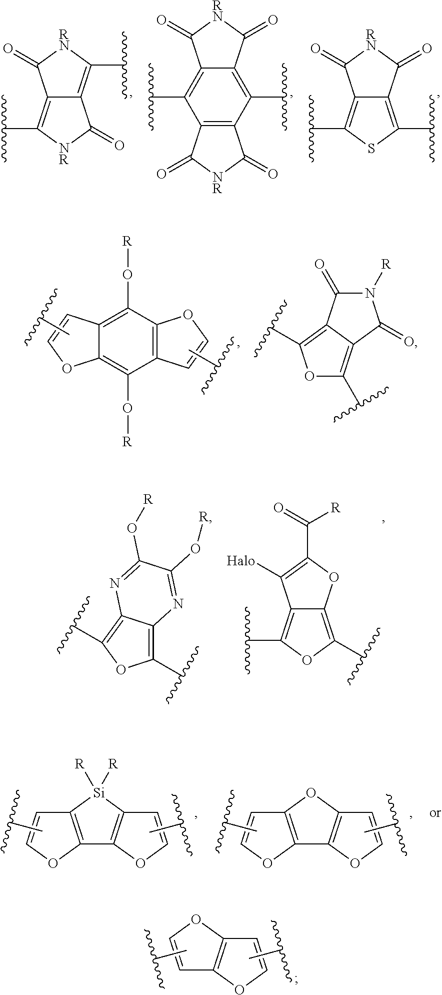
wherein each R is independently selected from hydrogen, an optionally substituted hydrocarbon, and a hetero-containing group, each Ar is independently selected from optionally substituted aryl and heteroaryl groups, each M is an optional, conjugated moiety, a represents a number that is at least 1, b represents a number from 0 to 20, n represents a number that is greater than 1, Halo is a halogen, and at least one Ar or M is a furan.

2. The polymer of claim 1, wherein the polymer has a narrow or low band gap, and/or is solution processable.

3. The polymer of claim 1, wherein the polymer comprises the following chemical structure: 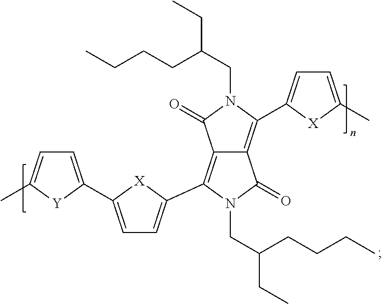
wherein X and Y are independently O or S.

4. The polymer of claim 3, wherein X is O.

5. The polymer of claim 3, wherein Y is O.

6. The polymer of claim 4, wherein Y is S, wherein the polymer is PDPP2FT.

7. The polymer of claim 4, wherein Y is O, wherein the polymer is PDPP3F.

8. A device comprising the polymer of claim 1.

9. The device of claim 8, wherein the device is a light-emitting diode, thin-film transistor, chemical biosensor, non-emissive electrochromic, memory device, or photovoltaic cell.

10. The device of claim 9, wherein the device comprises (a) the polymer of claim 1 is a p-type component, and (b) a suitable n-type component.

11. A photovoltaic device comprising a photoactive layer comprising the polymer of claim 1 disposed between a first electrode and a second electrode.

12. The photovoltaic device of claim 11, wherein the first electrode is ITO.

13. The photovoltaic device of claim 11, wherein the second electrode is LiF/Al.

14. The photovoltaic device of claim 11, wherein the photoactive layer, the first electrode, and the second electrode are thin films.

15. The photovoltaic device of claim 14, wherein the device further comprises a suitable substrate, wherein the thin films are disposed on the substrate.

16. The photovoltaic device of claim 15, wherein the substrate comprises glass.
